(19) United States
(12) Patent Application Publication
(10) Pub. No.: US 2011/0256385 A1
(43) Pub. Date: Oct. 20, 2011

(54) BONDING FILM-ATTACHED SUBSTRATE AND BONDING FILM-ATTACHED SUBSTRATE MANUFACTURING METHOD

(75) Inventors: Fumitake MATSUZAKI, Minowa-machi (JP); Mitsuru MIYABARA, Minamiminowa-mura (JP); Takehiko UEHARA, Minowa-machi (JP)

(73) Assignee: SEIKO EPSON CORPORATION, Tokyo (JP)

(21) Appl. No.: 13/078,394

(22) Filed: Apr. 1, 2011

(30) Foreign Application Priority Data
Apr. 15, 2010 (JP) 2010-093741

(51) Int. Cl. B32B 5/00; C23C 14/34; B05D 3/14; G02B 5/18

(52) U.S. Cl. 428/336; 359/566; 204/192.1; 427/488

(57) ABSTRACT

A bonding film-attached substrate includes: a substrate whose main component is not silicon dioxide, or that does not have a Si-group skeleton; a silicon oxide film formed on a surface of the substrate and adjacent to the substrate using a vapor-phase deposition method, and that has a thickness of from 100 nm to 2,000 nm, inclusive; and a bonding film provided by plasma polymerization, wherein the bonding film includes (i) a Si skeleton that contains a siloxane (Si—O) bond, and has a crystallinity of 45% or less, and (ii) an elimination group that binds to the Si skeleton, the elimination group being an organic group.

### BACKGROUND

1. Technical Field

The present invention relates to bonding film-attached substrates and bonding film-attached substrate manufacturing methods.

2. Related Art

Optical devices such as digital still cameras use optical low-pass filters (JP-A-2003-248198, Patent Document 1). In one variation, the optical low-pass filter is structured as a laminate of a crystalline birefringent plate, an IR (infrared) absorbing glass, a crystalline retardation plate (specifically, ¼ wave plate, also known as a depolarizing plate), and a crystalline birefringent plate. Of these optical components, the surface of the crystalline birefringent plate disposed on the outer side is coated with a reflection preventing film or a UV (ultraviolet)-IR cut coating.

Known examples of IR absorbing glass include an infrared cutoff filter that includes an infrared absorbing film on a substrate that has an infrared absorbing function imparted by adding CuO to a phosphate glass base material (JP-A-2008-70827, Patent Document 2), and infrared cutoff filters provided with an infrared absorbing film on a substrate of a material such as fused quartz (JP-A-2008-70828, Patent Document 3; JP-A-2008-70825, Patent Document 4).

In the infrared cutoff filter of Patent Document 2, a titanium oxide (TiO₂) thin film and a silicon dioxide (SiO₂) thin film are alternately laminated in repeating units as infrared absorbing films from the substrate side. In the infrared cutoff filters of Patent Documents 3 and 4, a TiO₂ or ITO thin film and a silicon oxide thin film are alternately laminated in contact with the substrate.

In the related art, the crystalline birefringent plate, the IR absorbing glass, or other optical members forming the optical low-pass filter are commonly bonded to each other with an adhesive.

However, the crystalline birefringent plate provided with a reflection preventing film or a UV-IR cut coating develops a warp in response to compressional stress or tensile stress, and as such the adhesive bonding of the crystalline birefringent plate to the IR absorbing glass or retardation plate produces nonuniform bonding layer thicknesses over the bonded surface, and causes serious wavefront aberrations.

Further, because the adhesive tends to undergo alteration by the reflow heat during the assembly of the optical low-pass filter, discoloration or adhesion failure occurs. Further, the use of an adhesive often causes defects in a high-humidity environment, where the adhesive spreads out from the periphery of the bonded layer of the optical members in branch patterns.

As a countermeasure, a method that directly bonds two substrates without using an adhesive has been proposed as an alternate means of bonding (JP-A-07-30354, Patent Document 5).

Further, JP-A-2007-41117 (Patent Document 6) proposes directly bonding substrates in an optical element fabricated as a laminate of two or more substrates, whereby the surface (bonding face) of one of the substrates is provided with a silicon oxide film (SiO₂ film), and directly bonded to the bonding face of the other substrate by interatomic bonding (Si—O—Si bonds or Si—Si bonds). In Patent Document 6, the laminated substrates are described as being quartz crystal plates, glass plates, or quartz crystal plates and glass plates.

However, the method involves difficulties in manufacture, because the direct bonding requires a high-temperature heat treatment (700 to 800° C.) of the substrate, or use of HF (hydrofluoric acid) during the hydrophilic treatment of the substrate bonding face. The method also has a detachment problem, which occurs during the heat treatment or in a high temperature environment during manufacturing steps due to the different linear coefficients of expansion between the substrate materials and between substrate quartz crystal planes. Another problem is that the bond strength becomes unstable depending on the conditions of the bonding face (such as uniformity, and cleanness).

As non-direct methods of bonding substrates without using an adhesive, bonding methods using a technique such as plasma polymerization have been proposed (Japanese Patent No. 4337935, Patent Document 7; JP-A-2009-173949, Patent Document 8).

In the methods of Patent Documents 7 and 8, a bonding film is formed on the bonding face of one of or both of the substrates by plasma polymerization, and the substrates are bonded to each other via the bonding film(s).

The bonding films disclosed in Patent Documents 7 and 8 include (i) a Si skeleton that has siloxane (Si—O) bonds, and a crystallinity of 45% or less, and (ii) organic elimination groups that bind to the Si skeleton. The laminate produced by the methods of these publications develops excellent adhesion.

JP-A-2009-98465 (Patent Document 9) discloses a polarizer fabricated by bonding a glass substrate and a polarization film with the bonding film disclosed in Patent Documents 7 and 8.

JP-A-2009-258404 (Patent Document 10) discloses a laminated wave plate fabricated by bonding a pair of quartz crystal substrates with the bonding film disclosed in Patent Documents 7 and 8.

JP-A-2009-192868 (Patent Document 11) discloses a polarization converter fabricated as a laminate of a first translucent substrate, a polarization separation film, a crystalline ½ wave plate, and a second translucent substrate laminated in order using the bonding film disclosed in Patent Documents 7 and 8.

Some types of glass contain the raw material silicon dioxide (SiO₂) as a main component, and various metal compounds mixed as subcomponents in the form of a powder. The manufacture of this type of glass involves quenching a liquid glass obtained by high-temperature melting. Examples of common subcomponents include sodium oxide (Na₂O), magnesium oxide (MgO), calcium oxide (CaO), boron oxide (B₂O₅), and phosphorus oxide (P₂O₅).

On the other hand, there is a substance that does not contain silicon dioxide (SiO₂) as a main component, but has a structure similar to that of glass, specifically, a substance that vitrifies. For example, boron oxide (B₂O₅) or phosphorus oxide (P₂O₅) contained as the main component instead of silicon dioxide makes up a skeleton and forms glass. The copper-containing glass substrate of phosphate glass or fluorophosphate glass base material disclosed in Patent Document 2 is an example of such glass.

However, Patent Documents 2, 3, and 4 do not disclose anything about a method of bonding an infrared cutoff filter element to a substrate such as a crystalline birefringent plate and a depolarizing plate (¼ wave plate). It then might be possible to bond the glass substrate of a main component substance other than silicon dioxide as disclosed in Patent Document 2 to other substrate using a bonding film such as those proposed in Patent Documents 7 and 8.

Patent Documents 7 and 8 introduce a wide variety of substrates as the bonding target. However, these publications do not make detailed assessments concerning problems associated with different materials, or effectiveness of bonding for these materials. A reproductive study conducted by the inventors of the present invention showed that the bonding was accurate and effective for silicon oxide glass (fused quartz) and silicon oxide alkaline glass. However, the study identified the following problem for phosphate glass members (IR absorbing glass members), a substrate not mentioned in the foregoing publications.

Specifically, sufficient bond strength could not be obtained when a bonding film formed by plasma polymerization as proposed in Patent Documents 7 and 8 was used to bond the CuO-containing IR absorbing glass member of phosphate glass base material disclosed in Patent Document 1 to a translucent substrate that contained silicon dioxide (SiO₂) such as fused quartz and quartz crystal as a main component.

Presumably, this is because the IR absorbing glass member, as a phosphate glass member, does not have a skeleton of Si-groups, and thus cannot form Si—O—Si siloxane bonds.

Further, the glass substrate used for the infrared cutoff filter of Patent Document 1 is doped with CuO or other impurities for infrared absorption, and thus does not have chemical durability comparable to that of silicon oxide glass such as fused quartz. Thus, the copper ions or other substances in the glass substrate undergo chemical reaction with water in the atmosphere in a high-humidity environment, and crystallize on the surface to produce micro foreign objects. It was found that such fine foreign objects become a factor that further inhibits the bonding that uses a bonding film formed by plasma polymerization.

Further, when the foreign objects precipitate in the bonded state, detachment becomes likely at the bond interface, and the bonding face pushes upward in different parts of the film and creates a space, which impairs the bonding film adhesion.

Studies conducted by the inventors of the present invention identified problems when an optical element produced by bonding materials having different linear coefficients of expansion, namely, a quartz crystal and a translucent substrate, such as glass, that does not have Si groups, or does not contain silicon dioxide (SiO₂) as a main component, is used by being incorporated in a product such as a projector, a digital still camera, and an optical pickup device. Specifically, because the quartz crystal and the translucent substrate have different linear coefficients of expansion, heat strain occurs depending on the temperature of the environment the product is used (operation temperature range), as these materials with different coefficients of thermal expansion expand and contract in different degrees. Further, because the bonding film bonding the quartz crystal and the translucent substrate cannot form siloxane (Si—O—Si) bonds with the translucent substrate, bonding reliability cannot be ensured. The bond thus cannot withstand the heat strain that depends on temperature changes, and defects such as detachment at the bond interface occur, with the result that sufficient bond strength cannot be obtained. That is, there is a problem that sufficient optical characteristics and reliability cannot be ensured for the optical element because of defects such as the detachment at the bond interface between the quartz crystal and the translucent substrate.

Specifically, it is difficult to obtain sufficient bond strength in bonding substrates of different materials, when the main component of the substrate is not silicon dioxide (SiO₂), or when the substrate does not have a skeleton of Si groups.

Further, the bonding method that uses the bonding film produced by plasma polymerization requires a manufacturing method that ensures flatness of the bonded film surface (small warp), or flexibility of the polymerization film for improved bond strength between the substrates.

### SUMMARY

An advantage of some aspects of the invention is to provide a bonding film-attached substrate and a manufacturing method thereof that can be used for the reliable bonding of substrates that do not contain silicon dioxide (SiO₂) as a main component, or do not have a Si-group skeleton, or for the reliable bonding of such a substrate with a substrate that contains silicon dioxide (SiO₂) as a main component, or has a Si-group skeleton.

### Application Example 1

A bonding film-attached substrate according to this application example includes: a substrate whose main component is not silicon dioxide, or that does not have a Si-group skeleton; a silicon oxide film formed on a surface of the substrate and adjacent to the substrate using a vapor-phase deposition method, and that has a thickness of from 100 nm to 2,000 nm, inclusive; and a bonding film provided by plasma polymerization, wherein the bonding film includes (i) a Si skeleton that contains a siloxane (Si—O) bond, and has a crystallinity of 45% or less, and (ii) an elimination group that binds to the Si skeleton, the elimination group being an organic group, and wherein the bonding film in response to energy imparted to at least a region of the bonding film develops adhesion for the substrate and for an adherend in the energy imparted region on a bonding film surface as a result of the elimination group being eliminated from the Si skeleton in the vicinity of the bonding film surface.

According to the application example configured as above, the bonding film-attached substrate can be strongly bonded to an adherend by the Si—O—Si siloxane bonds, because the bonding film-attached substrate has a bonding film provided by plasma polymerization.

Further, because the bonding film provided by plasma polymerization is not fluidic, the problems associated with the use of an adhesive, for example, accuracy failure such as wavefront aberrations due to nonuniform bond thicknesses over the film, can be avoided. Further, because the bonding film has elastic force, the bonding film can accommodate the bonding of members having different linear coefficients of expansion. Further, because the bonding film provided by plasma polymerization has heat resistance and resistance to high-humidity environment, the bonding film-attached substrate can desirably be used even under high temperature and high humidity conditions.

Further, because the substrate that does not contain silicon dioxide (SiO₂) as a main component, and does not have a silicon (Si)-group skeleton is provided with the silicon oxide film using a vapor-phase deposition method, precipitation of foreign objects, for example, such as copper ions and other impurities from the substrate surface can be blocked by the silicon oxide film. Because the bonding of the bonding film is not inhibited by such precipitated foreign objects, and detachment does not occur at the bonded portion, a high-quality, stable bond can be obtained. Further, because silicon oxide molecules in particular can provide an amorphous film with a high filling rate, the fine silicon oxide molecules enter the substrate, and a large Van der Waals' force can be obtained with the reduced distances between the molecules. The adhesion between the substrate and the silicon oxide film thus becomes desirable. In contrast, in Patent Document 2, a titanium oxide thin film is formed in contact with a CuO-containing substrate of phosphate glass base material. However, because the titanium oxide itself does not have a sufficient amorphous structure, detachment may occur in the bonded film as a result of precipitation of foreign objects such as CuO. Further, the titanium oxide film (IR cut member) of Patent Document 2 has a relatively smaller Van der Waals' force for the IR absorbing glass member than the silicon oxide film. The adhesion strength between the IR absorbing glass member and the titanium oxide film is therefore weak.

In this application example, the silicon oxide film is formed, and thus stable adhesion can be obtained by the formation of stable siloxane bonds as in the case of the bonding film. Note that a convex warp may develop in the flat surface of the substrate after the deposition of the silicon oxide film. However, because the bonding film has elastic force, the substrate bonded to an adherend does not detach from the adherend. Further, because the substrate under tension is accompanied by a warp that simultaneously develops in the adherend, almost no wavefront aberration occurs as a result of a warp introduced by the silicon oxide film.

In this application example, the silicon oxide film has a thickness of from 100 nm to 2,000 nm, inclusive. With a silicon oxide film thickness less than 100 nm, the silicon oxide film cannot suppress precipitation of copper ions and other foreign objects from the substrate surface. On the other hand, with a thickness above 2,000 nm, the substrate develops a more serious warp. When the silicon oxide film is formed using, for example, vapor deposition or sputtering, foreign objects such as a splash adhere to the surface and create surface projections. This impairs plane accuracy, and the bond strength becomes insufficient. The substrate and the adherend can thus be strongly bonded to each other when the silicon oxide film has a thickness of from 100 nm to 2,000 nm, inclusive.

Further, the bonding film provided by plasma polymerization can absorb the heat strain that occurs as the substrate and the adherend expand and contract in different degrees with temperature changes due to the different linear coefficients of expansion after being bonded to each other via the bonding film.

Further, because the bonding film and the silicon oxide film have the same Si skeleton and O skeleton when disposed adjacent to each other, very strong covalent bonds can be formed. The bond strength can thus be prevented from being lowered by the heat strain.

Because the heat strain can be absorbed and strong bond strength is maintained even with temperature changes, the substrate and the adherend can be prevented from being detached from each other, and desirable optical characteristics can be exhibited.

In this manner, the bonding film-attached substrate of the application example of the invention can be reliably bonded to an adherend, even when the adherend does not contain silicon dioxide as a main component, or does not have a Si-group skeleton, or when the adherend contains silicon dioxide as a main component, or has a Si-group skeleton.

Note that the bonding film according to the application example of the invention may be provided on the silicon oxide film either continuously or discontinuously.

Specifically, the invention may be configured to include the substrate, the silicon oxide film, and the bonding film continuously in this order, or may include the substrate, the silicon oxide film, the optical function film, and the bonding film continuously in this order. In this case, the optical function film may be, for example, a UV cut filter film, an IR cut filter film, a UV-IR cut filter film, or a polarization separation film.

### Application Example 2

According this application example, the bonding film-attached substrate is configured such that a total content of Si atoms and O atoms in all atoms forming the bonding film excluding H atoms is from 10 atom % to 90 atom %, inclusive.

According to this application example configured as above, the Si atoms and O atoms in the bonding film form a strong network, and the bonding film itself is strong. Further, the bonding film has particularly high bond strength for the substrate and the adherend.

### Application Example 3

According to this application example, the bonding film-attached substrate is configured such that the ratio of Si atoms and O atoms present in the bonding film is 3:7 to 7:3.

According to this application example configured as above, the bonding film has improved stability, and can bond the substrate and the adherend even more strongly.

### Application Example 4

According to this application example, the bonding film-attached substrate is configured such that the elimination group is an alkyl group.

According to this application example configured as above, because the alkyl group has high chemically stability, the bonding film that includes an alkyl group as the elimination group excels in weather resistance and chemical resistance.

### Application Example 5

According to this application example, the bonding film-attached substrate is configured such that the bonding film has an unbound atom or a hydroxyl group as an active bond after the elimination of the elimination group from the Si skeleton at least in the vicinity of the bonding film surface.

According to this application example configured as above, the bonding film-attached substrate can be strongly bonded to the adherend based on chemical bonds.

### Application Example 6

According to this application example, the bonding film-attached substrate is configured such that the bonding film includes polyorganosiloxane as a main material, and wherein a polymerization product of octamethyltrisiloxane is the main component of the polyorganosiloxane.

According to this application example configured as above, because octamethyltrisiloxane is relatively flexible, the stress due to the thermal expansion of the substrate and the adherend can be relieved, even when these members have different linear coefficients of expansion. Further, because the polyorganosiloxane has superior chemical resistance, the bonding film-attached substrate can be effectively used in an, environment exposed to chemicals or the like for extended time periods.

### Application Example 7

According to this application example, the bonding film-attached substrate is configured such that the substrate is a phosphate glass member.

According to this application example configured as above, the silicon oxide film can prevent precipitation of foreign objects such as copper ions and other impurities from the surface of the phosphate glass member. The bond strength of the bonding film provided by plasma polymerization can thus be stabilized.

### Application Example 8

According to this application example, the bonding film-attached substrate is configured such that a peak intensity ratio attributed to a methyl group is 0.05 or more and 0.15 or less with respect to the peak intensity 1 attributed to the siloxane bond in an infrared absorption spectrum.

According to this application example configured as above, because the peak intensity ratio attributed to the methyl group is 0.05 or more, the flexibility of the bonding film can be maintained. Thus, the substrate and the adherend can be prevented from being detached from each other by the differences in linear coefficient of expansion.

### Application Example 9

According to the present Application Example, the bonding film-attached substrate is configured such that a peak intensity ratio attributed to a Si—CH₃ bond is 0.29 or more and 0.76 or less with respect to the peak intensity 1 attributed to the siloxane bond in an infrared absorption spectrum.

According to this application example configured as above, because the peak intensity ratio attributed to the Si—CH₃ bond is 0.29 or more, the flexibility of the bonding film can be maintained. Thus, the substrate and the adherend can be prevented from being detached from each other by the differences in linear coefficient of expansion.

### Application Example 10

According to this application example, the bonding film-attached substrate in which the bonding film is activated by a plasma.

According to this application example configured as above, the plasma activation of the bonding film activates only the bonding film surface or areas in the vicinity of the surface of the bonding film, and thus changes in the content of the methyl groups, specifically, the elimination of the methyl groups inside the bonding film can be reduced. The substrate and the adherend can thus be bonded to each other with maintained flexibility.

On the other hand, in UV activation for example, because energy is imparted to also inside the bonding film, the methyl groups inside the bonding film are reduced, and the bonding film becomes hard. It is also difficult to control the number of methyl groups inside the bonding film.

### Application Example 11

According to this application example, the bonding film-attached substrate is configured such that the bonding film-attached substrate is used for an optical low-pass filter.

According to this application example configured as above, when the adherend is a retardation plate, the substrate can be strongly bonded to the retardation plate with the bonding film and the silicon oxide film. The substrate and the retardation plate can thus be prevented from being detached from each other even under heat strain, and can be suitably used for optical low-pass filters.

### Application Example 12

According to this application example, the bonding film-attached substrate is configured such that the bonding film-attached substrate is used for a polarization separation element.

According to this application example configured as above, when the adherend is a retardation plate, the substrate can be strongly bonded to the retardation plate with the bonding film and the silicon oxide film. The substrate and the retardation plate can thus be prevented from being detached from each other even under heat strain, and can be suitably used for polarization separation elements.

### Application Example 13

According to this application example, the bonding film-attached substrate is configured such that a polarization separation film is provided on the substrate in a portion facing the bonding film, wherein the polarization separation film is configured as a plurality of layers that includes the silicon oxide film and a magnesium fluoride thin film, the silicon oxide film being adjacent to the bonding film.

According to this application example configured as above, because the silicon oxide film is adjacent to the bonding film, the bonding film and the polarization separation film can form strong covalent bonds. The substrate and the polarization separation film can thus be prevented from being detached from each other.

### Application Example 14

According to this application example, the bonding film-attached substrate is configured such that the bonding film-attached substrate is used for an aperture filter.

According to this application example configured as above, when the adherend is a wave plate for aperture filters, the substrate can be strongly bonded to the wave plate for aperture filters with the bonding film and the silicon oxide film. The substrate and the wave plate for aperture filters can thus be prevented from being detached from each other even under heat strain, and can be suitably used for aperture filters.

### Application Example 15

According to this application example, the bonding film-attached substrate is configured such that the bonding film-attached substrate is used for a wave plate equipped with a diffraction grating.

According to this application example configured as above, when the adherend is a retardation plate, the substrate can be strongly bonded to the retardation plate with the bonding film and the silicon oxide film. The substrate and the retardation plate can thus be prevented from being detached from each other even under heat strain, and can be suitably used for wave plates equipped with a diffraction grating.

### Application Example 16

A bonding film-attached substrate manufacturing method according to this application example includes: forming the silicon oxide film on the substrate by sputtering or vapor deposition in a temperature range of from 150° C. to 350° C., inclusive; and forming the bonding film by using plasma polymerization in a temperature range of from 40° C. to 150° C., inclusive.

According to this application example configured as above, because the silicon oxide film is formed on the substrate by sputtering or vapor deposition in a temperature range of from 150° C. to 350° C., the silicon oxide film formed on the substrate is hard and dense, and can sufficiently prevent precipitation of foreign objects from the substrate surface. Further, because the bonding film is formed in a temperature range of from 40° C. to 150° C., the methyl group content falls in an optimum range, and the bonding film can be made flexible. Thus, the bonding film can sufficiently accommodate the bonding of the substrate and the adherend even when these substrates have different linear coefficients of expansion.

### BRIEF DESCRIPTION OF THE DRAWINGS

The invention will be described with reference to the accompanying drawings, wherein like numbers reference like elements.

FIG. 1 is a schematic structure view of an optical element provided with a bonding film-attached substrate according to First Embodiment of the invention.

FIG. 2A is a cross sectional view representing a state in which a silicon oxide film is provided on a foreign object adhered to a substrate of the optical element; FIG. 2B is a plan view representing a state in which a silicon oxide film is provided on a foreign object adhered to a substrate of the optical element.

FIG. 3 is an exploded cross sectional view illustrating a relevant portion of the optical element.

FIG. 4 is a schematic diagram of a plasma polymerization apparatus used in First Embodiment.

FIG. 5A is a partial magnified view representing a state of the bonding film before energy is imparted; FIG. 5B is a partial magnified view representing a state of the bonding film after energy is imparted.

FIGS. 6A to 6D are diagrams explaining an optical element manufacturing method.

FIGS. 7A to 7D are diagrams explaining an optical element manufacturing method.

FIG. 8 is a schematic structure view illustrating a variation of the optical element.

FIG. 9 is a graph representing the relationship between the thickness and warp of a silicon oxide film and bond strength.

FIG. 10 is a graph representing the relationship between bonding film deposition temperature and the peak intensity ratio of methyl (CH₃) groups.

FIG. 11 is a graph representing the relationship between bonding film deposition temperature and the peak intensity ratio of Si—CH₃ bonds.

FIG. 12A is a schematic structure view of an optical element provided with a bonding film-attached substrate according to Second Embodiment of the invention; FIG. 12B is a magnified cross sectional view illustrating a relevant portion of the optical element.

FIGS. 13A to 13C are schematic diagrams representing the procedure of molding a bonding film.

FIGS. 14A and 14B are schematic diagrams explaining a bonding film activation step.

FIGS. 15A and 15B are schematic diagrams explaining a bonding step.

FIGS. 16A and 16B are schematic diagrams explaining a cutting step.

FIGS. 17A and 17B are schematic diagrams explaining an assembly step.

FIG. 18A is a schematic plan view of an optical element provided with a bonding film-attached substrate according to Third Embodiment of the invention; FIG. 18B is a schematic structure view illustrating the optical element.

FIG. 19 is a schematic structure view of an optical element provided with a bonding film-attached substrate according to Fourth Embodiment of the invention.

FIG. 20 is a schematic structure view illustrating a variation of the bonding film-attached substrate of an embodiment of the invention.

### DESCRIPTION OF EXEMPLARY EMBODIMENTS

The following describes First Embodiment of the present invention.

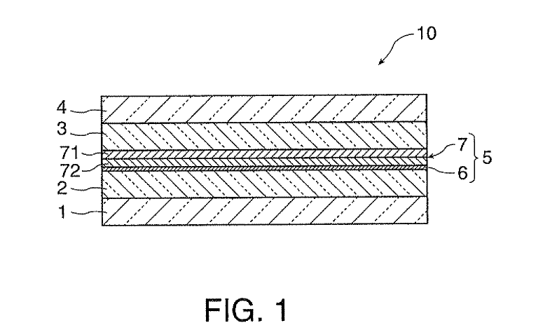

FIG. 1 illustrates a schematic structure of an optical element that includes a bonding film-attached substrate according to First Embodiment.

The optical element illustrated in FIG. 1 is an optical low-pass filter 10 that includes a laminate of a crystalline birefringent plate 1, an IR absorbing glass member 2, a retardation plate 3, and a crystalline birefringent plate 4.

The crystalline birefringent plate 1 is a flat-surface, crystalline rectangular planar member, and includes a reflection preventing film on the surface. The reflection preventing film has a 5-layer structure of alternately disposed low-refractive layers of, for example, silicon oxide, and high-refractive layers of, for example, titanium oxide.

The IR absorbing glass member 2 is a flat-surface, rectangular planar member formed from a phosphate glass member whose main component is P₂O₅, and is provided to cut infrared rays. IR absorbing glass member 2 is a substrate whose main component is not silicon dioxide (SiO₂), specifically, a substrate that does not include Si groups. The phosphate glass member contains large numbers of impurities such as copper ions, sodium ions, and calcium ions.

The retardation plate 3 is flat-surface, crystalline rectangular planar member, provided as an adherend for the IR absorbing glass member 2.

The crystalline birefringent plate 4 is flat-surface, crystalline rectangular planar member, and has a UV-IR cut coating formed on the surface. The UV-IR cut coating is configured to include, for example, alternately disposed 39 layers of low-refractive layer and high-refractive layer.

The IR absorbing glass member 2 and the retardation plate 3 are bonded to each other via a bonded portion 5. The IR absorbing glass member 2 and the bonded portion 5 correspond to the bonding film-attached substrate according to the invention.

The bonded portion 5 includes a silicon oxide film 6 formed adjacent to the surface of the IR absorbing glass member 2 using a vapor-phase deposition method, and a bonding film 7, formed by plasma polymerization, that molecularly bonds the silicon oxide film 6 and the retardation plate 3. The main material of the bonding film 7 is preferably polyorganosiloxane, as will be described later. The polyorganosiloxane is a collective term used to refer to polymeric compounds having siloxane bonds, and the main component is preferably the polymerization product of octamethyltrisiloxane.

The silicon oxide film 6 and the bonding film 7 formed adjacent to each other form stable siloxane bonds, and thus provide stable adhesion. The siloxane bonds have the patterns Si—O—Si, Si—Si, and Si—OH—Si.

The crystalline birefringent plate 1 and the IR absorbing glass member 2 are bonded to each other via a bonded portion (not illustrated) configured in the same manner as the bonded portion 5. The retardation plate 3 and the crystalline birefringent plate 4 are bonded to each other with a bonding film (not illustrated) provided by plasma polymerization.

In the present embodiment, the crystalline birefringent plate 1 and the retardation plate 3 are both optical members to be bonded to the IR absorbing glass member 2.

The bonding film 7 has an average thickness of preferably from 10 nm to 1,000 nm, inclusive, more preferably from 50 nm to 500 nm, inclusive. With an average thickness of the bonding film 7 less than 10 nm, the amount of elastic compression of the bonding film 7 becomes smaller, which creates non-adhering areas depending on the surface roughness or flatness of the retardation plate 3. Sufficient bond strength may not be obtained in this case. On the other hand, above 1,000 nm, cohesive failure tends to occur inside the bonding film 7, and the bond strength lowers. The bonding film 7 has a surface roughness Ra of 10 nm or less.

The total content of Si atoms and O atoms in all atoms forming the bonding film 7 excluding H atoms is preferably from 10 atom % to 90 atom %, inclusive. Further, the ratio of the Si and O atoms present in the bonding film 7 is preferably from 3:7 to 7:3.

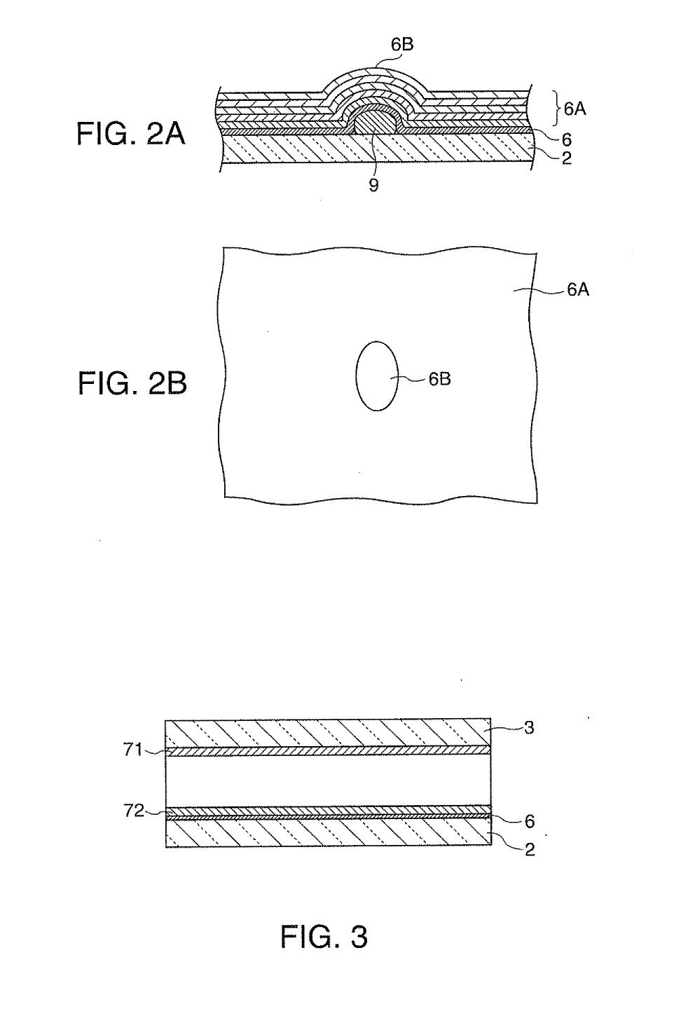

The silicon oxide film 6 has a thickness of from 100 nm to 2,000 nm, inclusive. With a thickness of the silicon oxide film 6 less than 100 nm, the silicon oxide film 6 fails to suppress precipitation of foreign objects such as copper ions from the surface of the IR absorbing glass member 2. On the other hand, above 2,000 nm, a large warp develops in the IR absorbing glass member 2. Further, when silicon oxide film 6 is deposited by, for example, vapor deposition or sputtering, the possibility of foreign object adherence increases in the bumping during the vapor deposition. When the silicon oxide film 6 is laminated on such foreign objects, projections occur on the surface of the silicon oxide film 6, and plane accuracy suffers. For example, as illustrated in FIGS. 2A and 23, when the silicon oxide film 6 is formed on a foreign object 9 present on the IR absorbing glass member 2, the projection 9 translates into a projection 6B of even a larger size upon forming a multilayer optical function film 6A on the silicon oxide film 6.

Thus, such projections resulting from the formation of a silicon oxide film exceeding 2,000 nm in thickness on the foreign object present on the IR absorbing glass member lead to insufficient bond strength.

The silicon oxide film 6 is deposited on the surface of the IR absorbing glass member 2 using a vapor-phase deposition method such as vapor deposition, sputtering, and CVD, as will be described later.

FIG. 3 is an exploded cross sectional view illustrating a relevant portion of the optical element.

As illustrated in FIG. 3, the bonding film 7, at the time of deposition, is divided into a thin film portion 71 formed on the retardation plate 3, and a thin film portion 72 formed on the silicon oxide film 6.

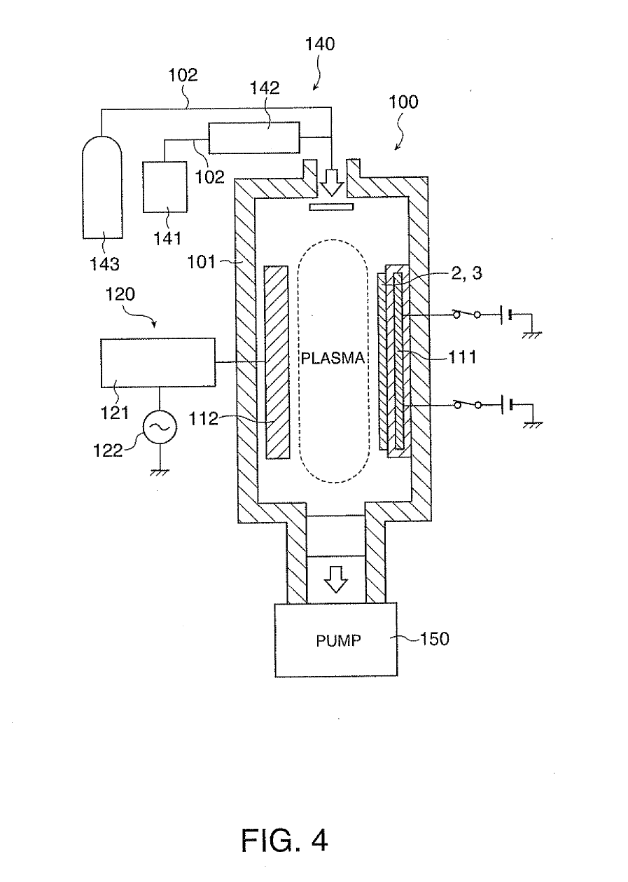

The thin film portions 71 and 72 are molded with a plasma polymerization apparatus illustrated in FIG. 4.

FIG. 4 is a schematic diagram of the plasma polymerization apparatus used in the present embodiment.

As illustrated in FIG. 4, the plasma polymerization apparatus 100 is structured to include a chamber 101, a first electrode 111 and a second electrode 112 provided inside the chamber 101, a power supply circuit 120 that applies high-frequency voltage between the first electrode 111 and the second electrode 112, a gas supply unit 140 that supplies gas into the chamber 101, and an evacuation pump 150 that evacuates the gas inside the chamber 101.

The first electrode 111 supports the deposition targets, specifically, the retardation plate 3, and the IR absorbing glass member 2 provided with the silicon oxide film 6.

The power supply circuit 120 includes a matching box 121 and the high-frequency power supply 122.

The gas supply unit 140 includes a liquid reservoir 141 that stores a liquid film material, a vaporizer 142 that vaporizes the liquid film material into a feedstock gas, and a gas cylinder 143 that stores carrier gas. The carrier gas stored in the gas cylinder 143 is a gas, for example, such as argon gas and helium gas, that discharges by the action of an electric field, and that is introduced into the chamber 101 to maintain the discharge.

The liquid reservoir 141, the vaporizer 142, the gas cylinder 143, and the chamber 101 are connected to one another via pipes 102, and a mixed gas of gaseous film material and carrier gas is supplied into the chamber 101.

The film material stored in the liquid reservoir 141 is the raw material used to form the thin film portions 71 and 72 of the bonding film 7 on the retardation plate 3 and on the IR absorbing glass member 2 provided with the silicon oxide film 6, using the plasma polymerization apparatus 100. The film material becomes a feedstock gas by being vaporized at the vaporizer 142.

Examples of feedstock gas include organosiloxanes such as methylsiloxane, hexamethyldisiloxane, octamethyltrisiloxane, decamethyltetrasiloxane, decamethylcyclopentasiloxane, octamethylcyclotetrasiloxane, and methylphenylsiloxane; organometallic compounds such as trimethylgallium, triethylgallium, trimethylaluminum, triethylaluminum, triisobutylaluminum, trimethylindium, triethylindium, trimethylzinc, and triethylzinc; various hydrocarbon compounds; and various fluorine compounds. Of these, octamethyltrisiloxanes are particularly preferred.

The thin film portions 71 and 72 of the bonding film 7 obtained from such feedstock gas is the result of the polymerization of these raw materials (polymerization product), specifically, the product of raw materials such as octamethyltrisiloxane.

Polyorganosiloxane is generally water repellent. However, polyorganosiloxane can be rendered hydrophilic by the elimination of the organic groups, which can easily be achieved with various activation processes.

The thin film portions 71 and 72, when formed from water-repellent polyorganosiloxane, hardly adhere to each other upon contact, because of the organic groups that inhibit adhesion. However, when formed from hydrophilic polyorganosiloxane, the thin film portions 71 and 72 can easily adhere to each other upon contact. Specifically, the advantage of easily controlling water repellency and hydrophilicity is advantageous in terms of easy control of adhesion, and thus the thin film portions 71 and 72 formed from polyorganosiloxane are preferably used in the present embodiment. Further, because polyorganosiloxane is relatively flexible, the stress due to the thermal expansion of the retardation plate 3 and the IR absorbing glass member 2 provided with the silicon oxide film 6 can be relieved even when these materials have different linear coefficients of expansion. Further, because polyorganosiloxane excels in chemical resistance, it can be effectively used for bonding members that are exposed to chemicals or the like for extended time periods.

Among different members of polyorganosiloxane, those including the polymerization product of octamethyltrisiloxane as the main component are preferred. The bonding film 7 that includes the polymerization product of octamethyltrisiloxane as the main component has superior adhesion, and can thus be preferably used in the bonding method of the present embodiment. The polymerization product of octamethyltrisiloxane is a liquid at ordinary temperature, and has appropriate viscosity, making it easy to handle.

The bonding film 7 has (i) a Si skeleton that has siloxane bonds and a crystallinity of 45% or less, and (ii) organic elimination groups that bind to the Si skeleton. The elimination groups are organic groups, preferably alkyl groups such as methyl (CH₃) groups. When energy is imparted to at least a region of the bonding film 7, the elimination groups in the vicinity of the surface of the bonding film 7 leave the Si skeleton, and the adhesion is developed between the IR absorbing glass substrate 2 and the retardation plate 3 in this surface region of the bonding film 7.

As illustrated in FIG. 3, the bonding film 7, at the time of deposition, is divided into the thin film portion 71 formed on the retardation plate 3, and the thin film portion 72 formed on the silicon oxide film 6. The structure of the thin film portion 71 is described below. Note that the thin film portions 71 and 72 have the structure.

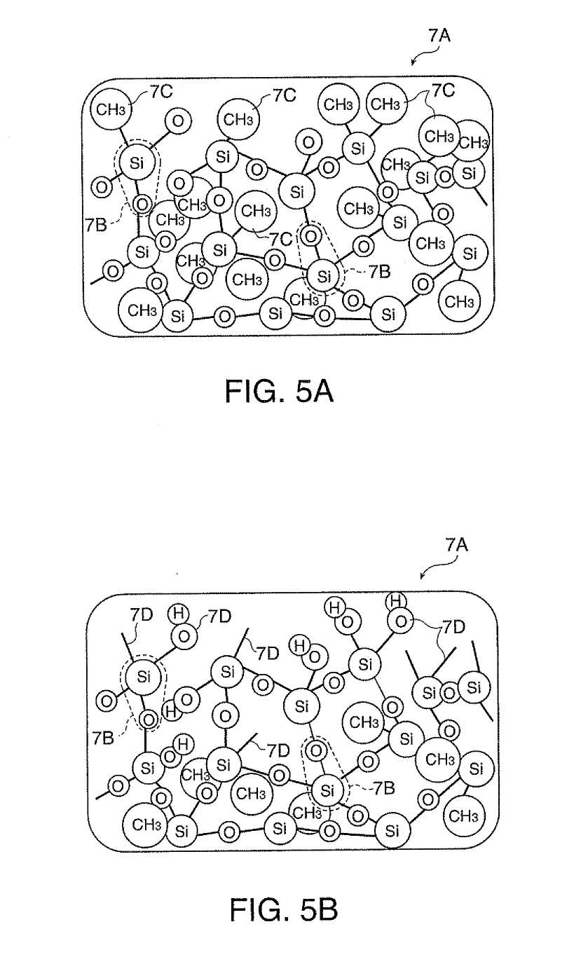

As illustrated in FIG. 5A, the thin film portion 71 has a Si skeleton 7A of a random atomic structure with siloxane (Si—O) bonds 7B, and elimination groups 7C that bind to the Si skeleton 7A. Because of the Si skeleton 7A of a random atomic structure with siloxane (Si—O) bonds 7B, the thin film portion 71 exists as a strong film that hardly undergo deformation. This is considered to be due to the low crystallinity of the Si skeleton 7A, limiting defects such as rearrangement and shifting at the crystal grain boundary. Thus, the thin film portion 71 itself has high bond strength, high chemical resistance, and high dimensional accuracy, and accordingly the resulting bonding film 7 also has high bond strength, high chemical resistance, and high dimensional accuracy.

When energy is imparted to the thin film portion 71, the elimination groups 7C leave the Si skeleton 7A, and, as illustrated in FIG. 5B, unbound active bonds 7D occur only on the surface or in the vicinity of the surface of the thin film portion 71. The active bonds may be hydroxyl groups. As a result, the thin film portion 71 develops adhesion on the surface. With this adhesion, the retardation plate 3 provided with the thin film portion 71 can bind to the silicon oxide film 6 provided with the thin film portion 72, both strongly and efficiently with high dimensional accuracy.

Further, the thin film portion 71 is solid-like with no fluidity. Thus, unlike the fluidic, liquid or viscous adhesive of the related art, the thin film portion 71 hardly changes its shape and thickness. This greatly improves the dimensional accuracy of the bonding film 7 over the related art. Further, because no time is required for curing the adhesive, strong bonds can be formed in a short time period.

Note that the Si skeleton 7A in the thin film portion 71 has a crystallinity of 45% or less, preferably 40% or less, and thus has a sufficiently random atomic structure. This brings out the characteristics of the Si skeleton 7A, and improves the dimensional accuracy and adhesion of the thin film portion 71.

Further, because the thin film portion 71 has the Si skeleton 7A and the O skeleton active bonds 7D, the thin film portion 71 exhibits strong bond strength by forming covalent bonds with the silicon oxide film 6 of the same skeleton structure.

The following describes a method for manufacturing the optical element provided with the bonding film-attached substrate according to First Embodiment.

### Silicon Oxide Film Deposition Step

First, the silicon oxide film 6 is deposited on the IR absorbing glass member 2 using a vapor-phase deposition method such as sputtering and vapor deposition. A known apparatus can be used for sputtering or vapor deposition. The deposition may be ion assisted, as required.

Specifically, the IR absorbing glass member 2 is placed in a chamber (not illustrated), and the silicon oxide film 6 is deposited on the IR absorbing glass member 2 with the temperature in the chamber set to 150° C. or more and 350° C. or less.

### Bonding Film Deposition Step

The thin film portions 71 and 72 that form the bonding film 7 are separately deposited on one surface of the retardation plate 3, and on the silicon oxide film 6 formed on the IR absorbing glass member 2. The deposition temperature is from 40° C. to 150° C., inclusive. In infrared absorption spectrum measurement, it is preferable that the peak intensity ratio attributed to the methyl (CH₃) group of the bonding film 7 be 0.05 or more and 0.15 or less, or that the peak intensity ratio attributed to the Si—CH₃ bond be 0.29 or more and 0.76 or less, with respect to the peak intensity 1 attributed to the siloxane bond (Si—O—Si).

The following describes the procedure of depositing the thin film portions 71 and 72.

In the polymerization film forming step, the retardation plate 3 and the silicon oxide film 6-deposited IR absorbing glass member 2 are held by the first electrode 111 inside the chamber 101 of the plasma polymerization apparatus 100. As oxygen is introduced into the chamber 101, the power supply circuit 120 applies high-frequency voltage between the first electrode 111 and the second electrode 112 to activate the retardation plate 3 and the silicon oxide film 6-deposited IR absorbing glass member 2.

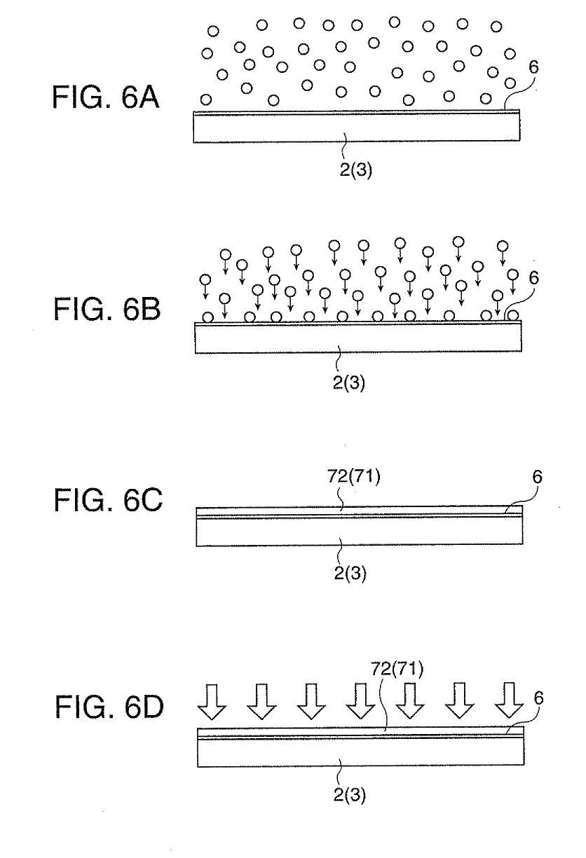

Thereafter, the gas supply unit 140 is activated, and a mixed gas of feedstock gas and carrier gas is supplied into the chamber 101. The mixed gas fills inside the chamber 101, and, as illustrated in FIG. 6A, one surface of the retardation plate 3 and the silicon oxide film 6 formed on the IR absorbing glass member 2 are exposed to the mixed gas.

The pressure inside the chamber 101 during the deposition is about 133.3×10⁻⁵ to 1,333 Pa (1×10⁻⁵ to 10 Torr). The flow rate of the feedstock gas is preferably about 0.5 to 200 sccm. The flow rate of the carrier gas is preferably about 5 to 750 sccm. The process time is preferably about 1 to 10 min.

In response to the applied high-frequency voltage between the first electrode 112 and the second electrode 112, the gas molecules between the electrodes 111 and 112 dissociate, and a plasma is generated. By the plasma energy, the molecules in the feedstock gas polymerize, and, as illustrated in FIG. 6B, the polymerization product adheres and deposit on one surface of the retardation plate 3 and the on the silicon oxide film 6 formed on the IR absorbing glass member 2. As a result, as illustrated in FIG. 6C, the thin film portions 71 and 72 of the bonding film 7 are formed on one surface of the retardation plate 3 and on the silicon oxide film 6 formed on the IR absorbing glass member 2, respectively.

### Surface Activation Step

Thereafter, as illustrated in FIG. 6D, the surfaces are activated by the activation of the thin film portions 71 and 72. The surface activation step may be performed by, for example, plasma irradiation, or by using other methods.

Preferably, the surface activation step is performed by plasma irradiation, in order to efficiently activate the surfaces of the thin film portions 71 and 72. The plasma may be, for example, oxygen, argon, nitrogen, air, water, which may be used either alone or as a mixture of two or more. Of these, oxygen is preferred.

The plasma activates only the surface or areas in the vicinity of the surface of the thin film portions 71 and 72, and thus prevents elimination of the methyl (CH₃) groups inside the bonding film, making it possible to form bonds with maintained flexibility. Further, the process can be finished in a shorter time period without producing large areas of nonuniformity.

In the thin film portions 71 and 72 activated in this manner, some of the methyl (CH₃) groups on the surface are eliminated, and become Si—OH by the introduction of Si— or OH groups.

### Bonding Step

The retardation plate 3, and the silicon oxide film 6 formed on the IR absorbing glass member 2 after the surface activation of the thin film portions 71 and 72 are bonded to each other into a single unit (bonding step).

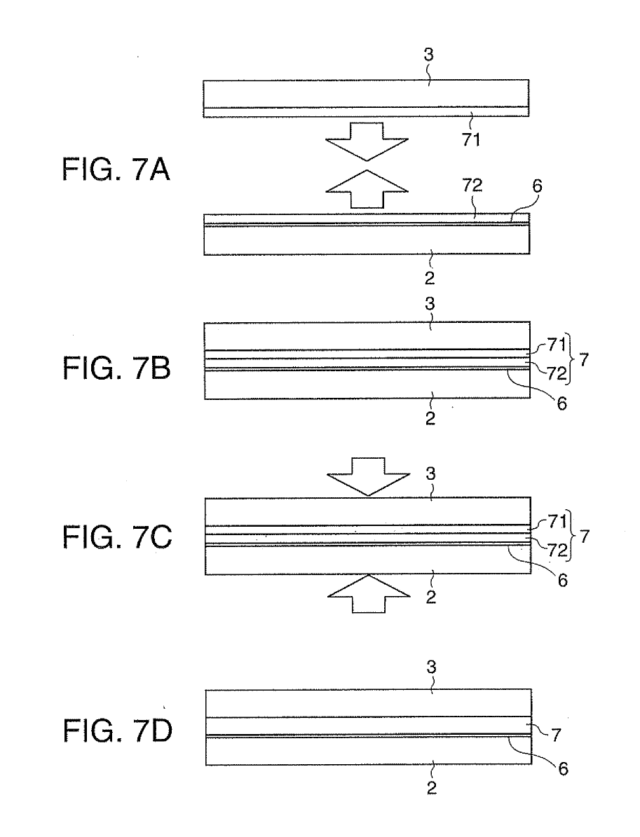

Specifically, as illustrated in FIGS. 7A and 7B, the retardation plate 3 and the silicon oxide film 6 formed on the IR absorbing glass member 2 are pressed against each other with the thin film portions 71 and 72 of the bonding film 7 facing each other.

Because the activated state of the surface activated thin film portions 71 and 72 attenuates with time, the transition from the surface activation step to the bonding step is prompt.

The films are bonded by the bonding between the thin film portions 71 and 72. It is assumed that the bonding of the films is based on the following mechanisms <1> and/or <2>.

<1> After the bonding of the two substrates (the retardation plate 3 and the silicon oxide film 6 formed on the IR absorbing glass member 2 in the present embodiment), the OH groups present on the surfaces of the thin film portions 71 and 72 of the bonding film 7 are adjacent to one another. The adjacent OH groups attract each other by hydrogen bonding, and an attractive force is created between the OH groups.

Further, the OH groups attracted to each other by hydrogen bonding are eliminated from the surfaces by a process that involves temperature-dependent dehydration condensation. As a result, the atoms previously bound to the eliminated OH groups bind to each other at the interface between the thin film portions 71 and 72.

<2> The unterminated atoms (unbound atoms) occurring at the surfaces or in the vicinity of the surfaces of the thin film portions 71 and 72 rejoin upon bonding the IR absorbing glass member 2 and the retardation plate 3. The rejoining of atoms occurs in a complicated manner that involves overlap (tangling) between the thin film portions 71 and 72, and thus a network of bonds is formed at the bonded interface. As a result, the silicon oxide film 6 provided with the thin film portion 72 is directly bonded to the retardation plate 3 provided with the thin film portion 71, and the thin film portions 71 and 72 becomes one unit.

### Pressurizing Step

In the present embodiment, as illustrated in FIG. 7C, the retardation plate 3 and the IR absorbing glass member 2 are pressurized after the bonding step, as required. The applied pressure brings the thin film portions 71 and 72 even closer to each other. As a result, the distances between the molecules become shorter, and increased numbers of molecules bind together. Further, the hydrogen bonds between some of the OH groups become Si—O—Si siloxane bonds, and strong, stable bonds are obtained. As a result, as illustrated in FIG. 7D, a part of the optical low-pass filter is fabricated. In the state where the retardation plate 3 and the IR absorbing glass member 2 are pressurized, the thin film portions 71 and 72 form the bonding film 7 as a single unit.

The applied pressure in the pressurizing step varies depending on such factors as the thicknesses of the retardation plate 3 and the IR absorbing glass member 2, and apparatus conditions. Preferably, the applied pressure is about 1 to 10 MPa.

The pressure application may be followed by heating.

These steps are performed for the crystalline birefringent plate 1, and for the IR absorbing glass member 2 bonded to the retardation plate 3. Specifically, a silicon oxide film (not illustrated) is deposited on the IR absorbing glass member 2, and the IR absorbing glass member 2 and the crystalline birefringent plate 1 are bonded to each other with a bonding film-forming thin film portion (not illustrated) deposited on the silicon oxide film and on one surface of the crystalline birefringent plate 1.

Further, the retardation plate 3 and the crystalline birefringent plate 4 are bonded to each other with a bonding film-forming thin film portion (not illustrated) deposited on the retardation plate 3 and on the crystalline birefringent plate 4.

The optical low-pass filter is fabricated after these steps.

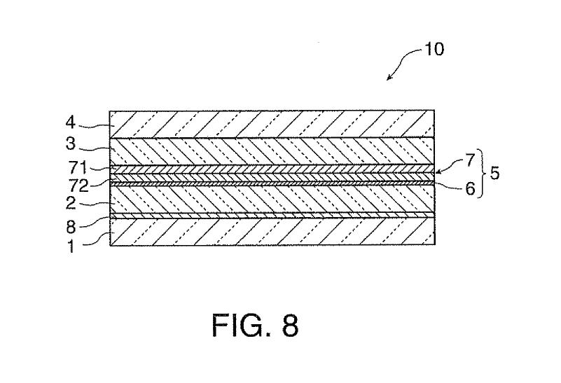

Note that the bonding film-attached substrate according to the invention may be configured as illustrated in FIG. 8. FIG. 8 is a schematic structure view illustrating a variation of the optical element. Specifically, the bonding film-attached substrate may be configured so that the IR absorbing glass member 2 has an infrared-cutting infrared absorbing film 8 on the side of the crystalline birefringent plate 1. The infrared absorbing film 8 is a laminate of dielectric films, and a known film may be used therefor.

The present embodiment of the configuration described above has the following advantages.

(1) The silicon oxide film 6 is formed on the IR absorbing glass member 2, and the silicon oxide film 6 is molecularly bonded to the crystalline retardation plate 3 via the bonding film 7. Thus, the silicon oxide film 6 and the retardation plate 3 are strongly bonded by the Si—O—Si siloxane bonds, and accordingly no adhesive is required. The bond thickness is therefore uniform, and wavefront aberration can be prevented. Further, because the bonding film 7 has elastic force, detachment is unlikely to occur at the bonded portion in response to factors such as temperature change, even when the IR absorbing glass member 2 and the retardation plate 3 have different linear coefficients of expansion. Further, because precipitation of foreign objects such as copper ions and other impurities from the surface of the IR absorbing glass member 2 can be blocked by the silicon oxide film 6, such foreign objects do not enter the bonding film 7, and detachment does not occur at the bonded portion.

(2) The main material of the bonding film 7 is polyorganosiloxane whose main component is the polymerization product of octamethyltrisiloxane. In this case, because the octamethyltrisiloxane is relatively flexible, the stress due to the different linear coefficients of expansion of the IR absorbing glass member 2 and the retardation plate 3 can be relieved. Further, because the polyorganosiloxane itself has excellent chemical resistance, the chemical resistance of the IR absorbing glass member 2 and the retardation plate 3 can be improved.

(3) Because the thickness of the silicon oxide film 6 is from 100 nm to 2,000 nm, inclusive, precipitation of foreign objects such as copper ions can be suppressed, and sufficient bond strength can be obtained.

(4) The deposition of the silicon oxide film 6 on the IR absorbing glass member 2 by a vapor-phase deposition method such as sputtering and vapor deposition is performed at 150° C. or more and 350° C. or less. This makes the silicon oxide film 6 hard and dense, and precipitation of foreign objects from the surface of the IR absorbing glass member 2 can be sufficiently prevented. Further, because the deposition of the bonding film 7 is performed at 40° C. or more and 150° C. or less, the bonding film 7 have appropriate flexibility. Note that the lower limit of deposition temperature is set to 40° C., because this is the temperature range that allows the deposition apparatus to stably control base material surface temperature. Accordingly, the deposition may be performed at room temperature around 20° C.

(5) The bonding film 7 is divided into the thin film portions 71 and 72. The thin film portion 72 is deposited on the silicon oxide film 6 of the IR absorbing glass member 2, and the thin film portion 71 is deposited on the retardation plate 3. Because the bonded portion of the pressurized films is the same material, the films can be bonded more strongly.

(6) In the bonding film 7, the peak intensity ratio attributed to the methyl (CH₃) group is set to 0.05 or more and 0.15 or less with respect to the peak intensity 1 attributed to the siloxane bond (Si—O—Si) in infrared absorption spectrum measurement. Further, the peak intensity ratio attributed to the Si—CH₃ bond is set to 0.29 or more and 0.76 or less. In this case, because the peak intensity ratio attributed to the methyl (CH₃) group is 0.05 or more, or because the peak intensity ratio attributed to the Si—CH₃ bond is 0.29 or more, the bonding film 7 can remain flexible. Note that the peak intensity ratio attributed to the methyl (CH₃) group, and the peak intensity ratio attributed to the Si—CH₃ bond decrease with increase in the deposition temperature of the bonding film 7.

(7) The retardation plate 3 and the IR absorbing glass member 2 having different linear coefficients of expansion are molecularly bonded to each other via the bonding film 7. Thus, heat strain that might occur in the retardation plate 3 and the IR absorbing glass member 2 due to differences in the extent of expansion and contraction in response to temperature changes can be absorbed by the bonding film 7.

Further, the bonding film 7 and the silicon oxide film 6 are bonded adjacent to each other. Because the bonding film 7 and the silicon oxide film 6 have the same Si skeleton and O skeleton, very strong covalent bonds can be formed. This prevents bond strength from being lowered even in the presence of heat strain, and the retardation plate 3 and the IR absorbing glass member 2 can be prevented from being detached.

(8) The total content of Si atoms and O atoms in all atoms forming the bonding film 7 excluding H atoms is set to 10 atom % to 90 atom %, inclusive. The Si atoms and O atoms in the bonding film 7 thus form a strong network. This improves the strength of the bonding film 7 itself. Further, the bonding film 7 exhibits high bond strength particularly for the IR absorbing glass member 2 and the retardation plate 3.

(9) The ratio of Si atoms and O atoms present in the bonding film 7 is set to 3:7 to 7:3. This improves the stability of the bonding film 7, and enables the IR absorbing glass member 2 and the retardation plate 3 to be bonded to each other more strongly.

(10) The bonding film 7 includes alkyl groups as the elimination groups, and thus excels in weather resistance and chemical resistance.

(11) The bonding film 7 has active bonds 7D, either unbound bonds or hydroxyl groups, after the elimination of the elimination groups 7C from the Si skeleton at least in the vicinity of the surface. This enables the IR absorbing glass member 2 and the retardation plate 3 to be strongly bonded to each other by chemical bonding.

(12) By the provision of the silicon oxide film 6 on the surface of the IR absorbing glass member 2 (phosphate glass member), precipitation of foreign objects such as copper ions and other impurities from the surface can be prevented. This stabilizes the bond strength of the bonding film 7.

(13) The activation of the bonding film 7 by a plasma can only activate the surface or areas in the vicinity of the surface of the bonding film 7. Thus, fewer methyl groups are eliminated inside the bonding film 7. The IR absorbing glass member 2 and the retardation plate 3 can thus be bonded to each other with maintained flexibility.

These effects of First Embodiment were ascertained based on Example, as follows.

First, the silicon oxide film 6 is described with regard to the relationship between its thickness and warpage, and the relationship with bond strength.

In this Example, the silicon oxide film 6 was deposited on the IR absorbing glass member 2 by ion-assisted deposition under the following conditions.

### Deposition Conditions

Deposition temperature: 150° C.

Acceleration voltage: 1,000V

Acceleration current: 1,200 mA

Rate: 7 angstrom/sec

### Conditions of IR Absorbing Glass Member 2

Thickness: 0.30 mm

Size: □ 40 mm

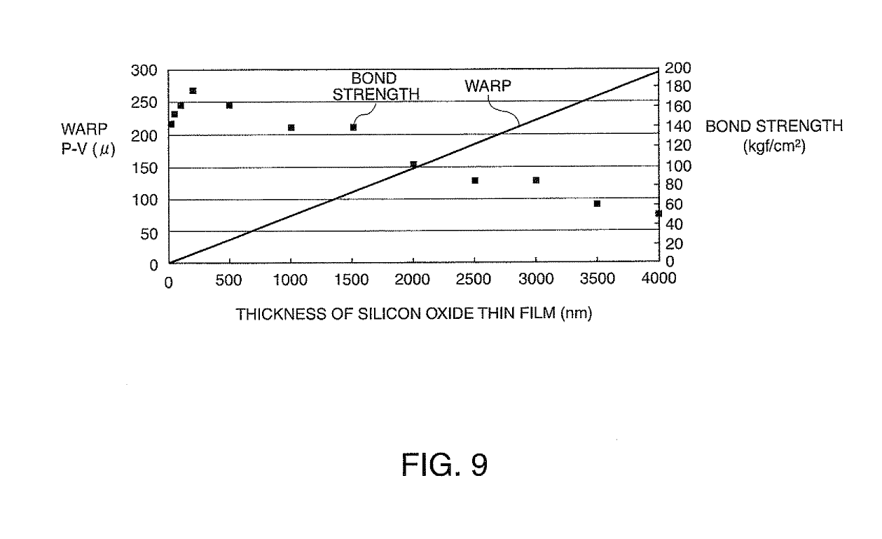

FIG. 9 is a graph representing the relationship between the thickness and warpage, and the bond strength of the silicon oxide film. Note that a warp was measured using a high-accuracy flatness tester (Model FT-900: Nidek Co., Ltd.), and the bond strength was measured with a tensile strength tester (Model AGS-H; Shimadzu Corporation).

As shown in FIG. 9, a warp increases in direct proportion to the thickness of the silicon oxide film. For example, a warp is 36.7μ at the silicon oxide film thickness of 500 nm, 73.5μ at 1,000 nm, 147.1μ at 2,000 nm, 220.7μ at 3,000 nm, and 294.3μ at 4,000 nm. On the other hand, the bond strength (tensile adhesion strength) is 1 kgf/cm² at the silicon oxide film thickness of 0 nm (no thin film), 82 kgf/cm² (kgf/cm²=9.80665 N/cm²) at 10 nm, 144 kgf/cm² at 20 nm, 153 kgf/cm² at 50 nm, 164 kgf/cm² at 100 nm, 178 kgf/cm² at 200 nm, 163 kgf/cm² at 500 nm, 139 kgf/cm² at 1,000 nm, 139 kgf/cm² at 1,500 nm, 102 kgf/cm² at 2,000 nm, 85 kgf/cm² at 2,500 nm, 84 kgf/cm² at 3,000 nm, 60 kgf/cm² at 3,500 nm, and 49 kgf/cm² at 4,000 nm. Specifically, a warp increases with increase in thickness of the silicon oxide film; however, the bond strength increases only until the silicon oxide film thickness is 200 nm, and starts to decrease as the thickness increases further. With a thickness of the silicon oxide film 6 above 2,000 nm, sufficient bond strength cannot be obtained because of such factors as the stress and surface roughness of the silicon oxide film 6, and adhesion of foreign objects in the bumping during the vapor deposition.

Preferably, the practical bond strength is 100 kgf/cm² or more in terms of a tensile adhesion strength (according to JIS K 6848). For these reasons, the thickness of the silicon oxide film 6 is preferably from 20 nm to 2,000 nm, inclusive. However, because the silicon oxide film needs to have a thickness of 100 nm or more to prevent precipitation of copper ions and other foreign objects from the IR absorbing glass member 2, the optimum thickness of the silicon oxide film is from 100 nm to 2,000 nm, inclusive, in the present embodiment.

The measured transmission wavefront PV in the Example in which the silicon oxide film-deposited IR absorbing glass member was bonded to the retardation plate via the bonding film was on average 0.8λ (λ=632.8 nm). In contrast, in Comparative Example in which the silicon oxide film-deposited IR absorbing glass member was bonded to the retardation plate via an adhesive, the measured transmission wavefront PV was 3.4λ, and the wavefront aberration was greater than in the Example in which the bonding film was used.

The following describes the relationship between the bonding film deposition temperature and the peak intensity ratio attributed to the methyl (CH₃) group or the Si—CH₃ bond with respect to the peak intensity 1 attributed to the siloxane bond (Si—O—Si) in infrared absorption spectrum measurement.

Si, Ar, and O₂ gases were used in the deposition apparatus with a flow rate of 30 sccm for Si, 30 sccm for Ar, and 0 sccm for O₂ under the pressure of 4 Pa and the power of 250 W. The deposition was preceded by the activation step, which was performed for 30 seconds with the O₂ gas introduced at a flow rate of 20 sccm at 50 W under the pressure of 4 Pa. Under these conditions, the relationship between the peak intensity ratio attributed to the methyl (CH₃) group and the peak intensity ratio attributed to the Si—CH₃ bond was examined at varying deposition temperatures.

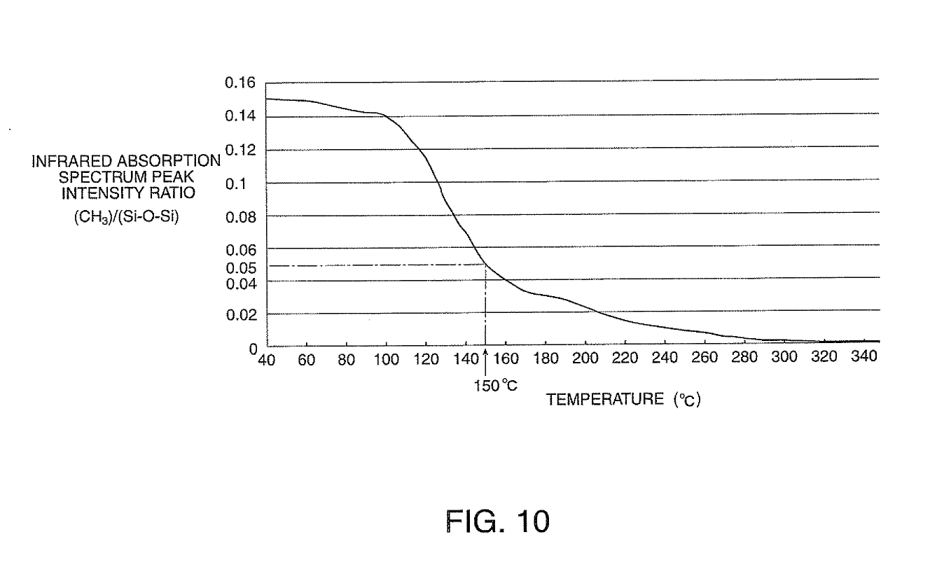

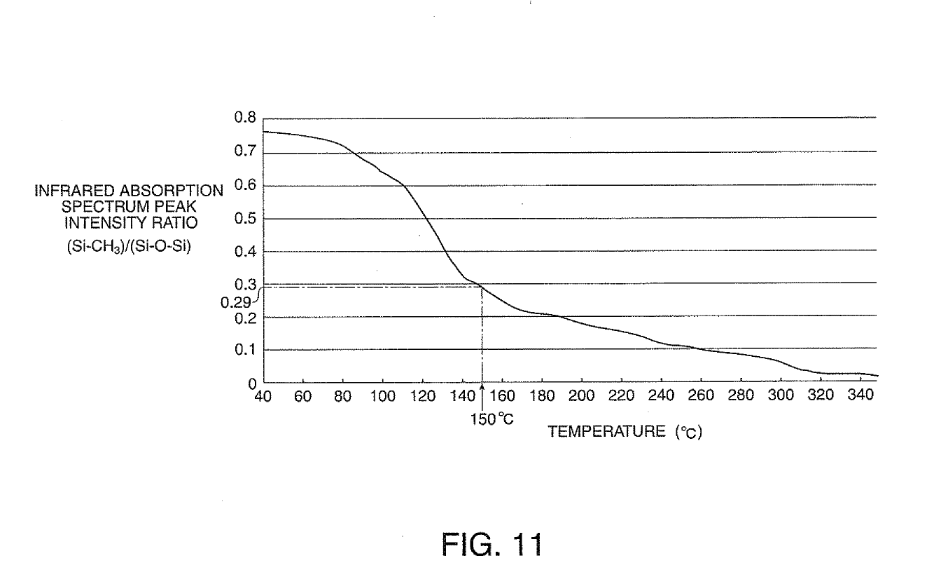

FIG. 10 is a graph representing the relationship between deposition temperature and the peak intensity attributed to the methyl (CH₃) group. FIG. 11 is a graph representing the relationship between deposition temperature and the peak intensity attributed to the Si—CH₃ bond. The data presented in these graphs are the average values of the experiment data.

It can be seen in FIG. 10 that the peak intensity ratio of the methyl (CH₃) group decreases as the deposition temperature increases. For example, the peak intensity ratio of the methyl (CH₃) group is 0.15 at the deposition temperature of 40° C., 0.15 at 50° C., 0.15 at 60° C., 0.147 at 70° C., 0.144 at 80° C., 0.142 at 90° C., 0.14 at 100° C., 0.07 at 140° C., 0.05 at 150° C., 0.04 at 160° C., and 0.033 at 170° C.

It can be seen in FIG. 11 that the peak intensity ratio attributed to the Si—CH₃ bond decreases as the deposition temperature increases. For example, the peak intensity ratio attributed to the Si—CH₃ bond is 0.76 at the deposition temperature of 40° C., 0.755 at 50° C., 0.75 at 60° C., 0.74 at 70° C., 0.72 at 80° C., 0.68 at 90° C., 0.64 at 100° C., 0.33 at 140° C., 0.29 at 150° C., 0.25 at 160° C., and 0.22 at 170° C.

At high deposition temperatures, the methyl (CH₃) groups and the Si—CH₃ bonds break, and the bonding film is oxidized, with the result that the proportion of the silicon oxide increases. This makes the bonding film hard, and the flexibility becomes insufficient, which creates problems in pressing the members for bonding.

Assessment of the polymerization film hardness at each deposition temperature revealed that deposition temperatures of from 40° C. to 150° C., inclusive, were sufficient to maintain the flexibility of the bonding film. With a deposition temperature above 150° C., the polymerization film becomes too hard, and the bonding face becomes no different from that seen in the direct bonding of the related art (bonding between the mirror-finished surfaces of silicon oxide glass). In this case, bonding is not possible unless the flatness of the bonding face is improved to a high level.

Thus, at deposition temperatures of from 40° C. to 150° C., inclusive, the peak intensity ratio of the methyl (CH₃) group is from 0.05 to 0.15, inclusive, and the peak intensity ratio of the Si—CH₃ bond is from 0.29 to 0.76, inclusive. In other words, the appropriate values of peak intensity ratio for the bonding of the bonding film 7 are 0.05 or more for the methyl (CH₃) group, and 0.29 or more for the Si—CH₃ bond.

### Second Embodiment

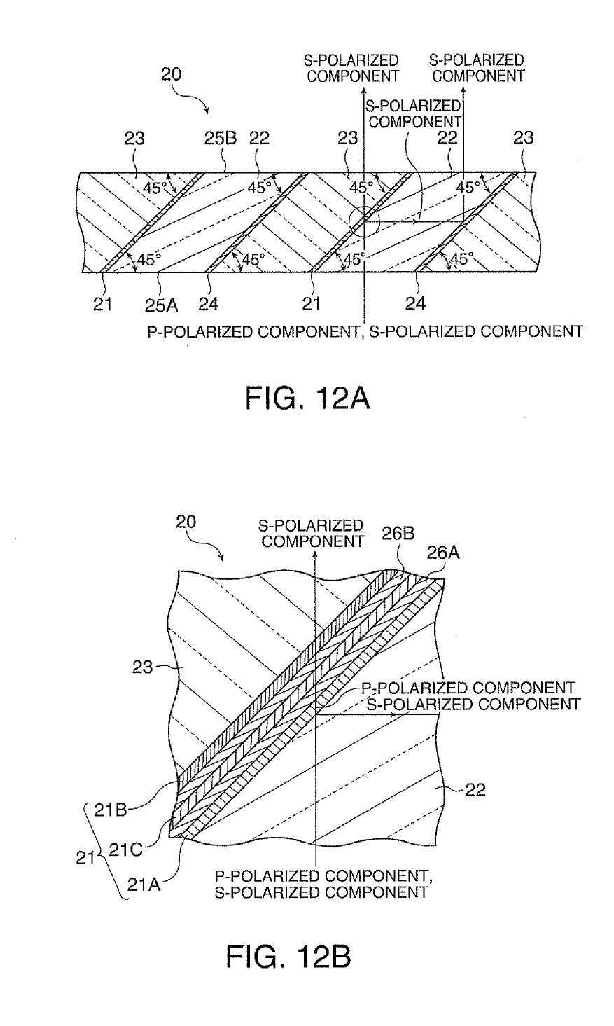

The following describes Second Embodiment of the present invention with reference to FIGS. 12A and 12B to FIGS. 16A and 16B. FIG. 12A is a schematic structure view illustrating an optical element provided with a bonding film-attached substrate according to Second Embodiment of the invention. FIG. 12B is a magnified cross sectional view illustrating a relevant portion of the optical element.

Second Embodiment is an example of the optical element as a polarization separation element 20, called a PS conversion element. The polarization separation element 20 is used by being incorporated in, for example, a liquid crystal projector.

In FIGS. 12A and 12B, the polarization separation element 20 of Second Embodiment is shown as a laminate that includes a first glass-base material 23, and a second glass-base material 22 provided as a substrate bonded to the first glass-base material 23 via a polarization separation-conversion layer 21 or a reflecting film 24. Note that the second glass-base material 22 does not include silicon dioxide as the main component, or does not have a Si-group skeleton, and is, for example, a phosphate glass member.

The first glass-base material 23 and the second glass-base material 22 have a light-incident side flat surface 25A and a light-emergent side flat surface 25B facing parallel to each other, and the reflecting film 24 and the polarization separation-conversion layer 21 are disposed parallel to each other with a 45° angle with respect to the flat surfaces 25A and 25B.

As illustrated in FIG. 12A, the polarization separation-conversion layer 21 separates the incident light beam (S-polarized light and P-polarized light) into S-polarized light and P-polarized light. The S-polarized light is reflected, and the P-polarized light is emitted as S-polarized light.

The polarization separation-conversion layer 21, as illustrated in FIG. 12B, includes a polarization separation film 21A adjoined and bonded to the second glass-base material 22, a silicon oxide film 21B laminated on the first glass-base material 23, and a ½ wave plate 21C (adherend) bonded to the polarization separation film 21A and the silicon oxide film 21B.

The polarization separation film 21A is configured as a laminate of alternately disposed layers of high-refractive index material and low-refractive index material on the surface of the second glass-base material 22.

Examples of the high-refractive index material include a lanthanum titanate film formed from a mixed oxide of La (lanthanum) and Ti (titanium), a lanthanum aluminate film formed from a mixed oxide of La and Al (aluminum), and various high-refractive index films of, for example, Ta₂O₅, TiO₂, Nb₂Oₛ, and Al₂O₃.

Example of the low-refractive index material include various low-refractive index films, such as a SiO₂ film formed from silicon dioxide, and a MgF₂ film formed from magnesium fluoride (MgF₂).

In the laminate of the layers appropriately selected from these high-refractive index materials and low-refractive index materials, a silicon oxide film of SiO₂ (not illustrated) similar to that described in First Embodiment, is disposed on the outermost layer of the polarization separation film 21A at the interface between the polarization separation film 21A and the ½ wave plate 21C. A silicon oxide film (not illustrated), similar to that described in First Embodiment, is also disposed on the outermost surface of the polarization separation film 21A at the interface between the polarization separation film 21A and the second glass-base material 22.

These silicon oxide films formed on the outermost layers may be laminated in such a manner that a silicon dioxide SiO₂ film, when selected as the low-refractive index material in the alternately disposed layers of high-refractive index material and low-refractive index material, is disposed on the outermost layers of these alternate layers.

The ½ wave plate 21C is bonded between the polarization separation film 21A and the silicon oxide film 21B, specifically, by bonding films 26A and 263, similar to the bonding film of First Embodiment. In other words, the polarization separation film 21A is provided on the second glass-base material 22 in a portion facing the bonding film 26A.

The reflecting film 24 shown in FIG. 12A is a film of multiple dielectric layers of different refractive indices, and is configured from, for example, tantalum oxide (TaO₅) and a silicon oxide film. Further, the reflecting film 24 is bonded to the first glass-base material 23 and the second glass-base material 22 using the same bonding method used for the polarization separation-conversion layer 21. The reflecting film 24 reflects the S-polarized light component reflected at the polarization separation film 21A, and bends the propagation direction 90° to direct the light to emerge through the flat surface 253 on the light emerging side.

### Polarization Separation Element Manufacturing Method

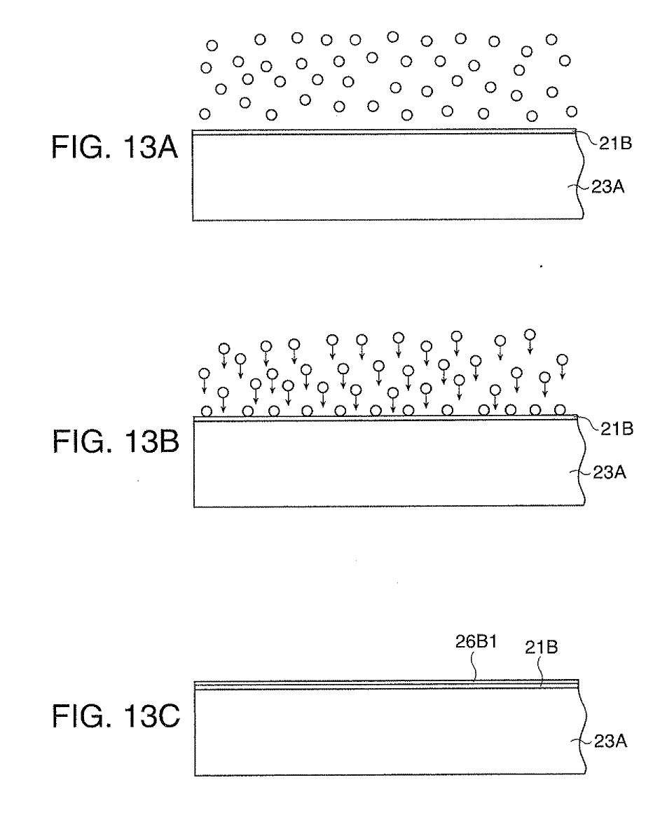

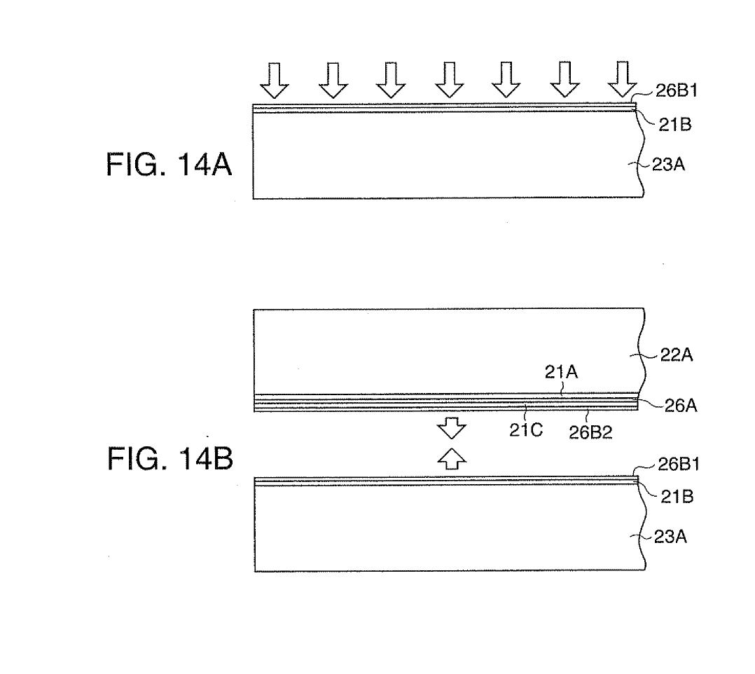

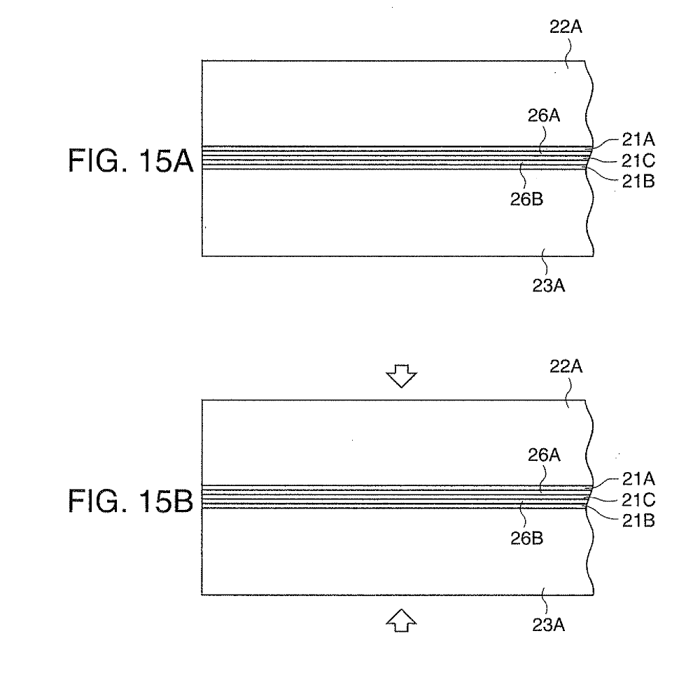

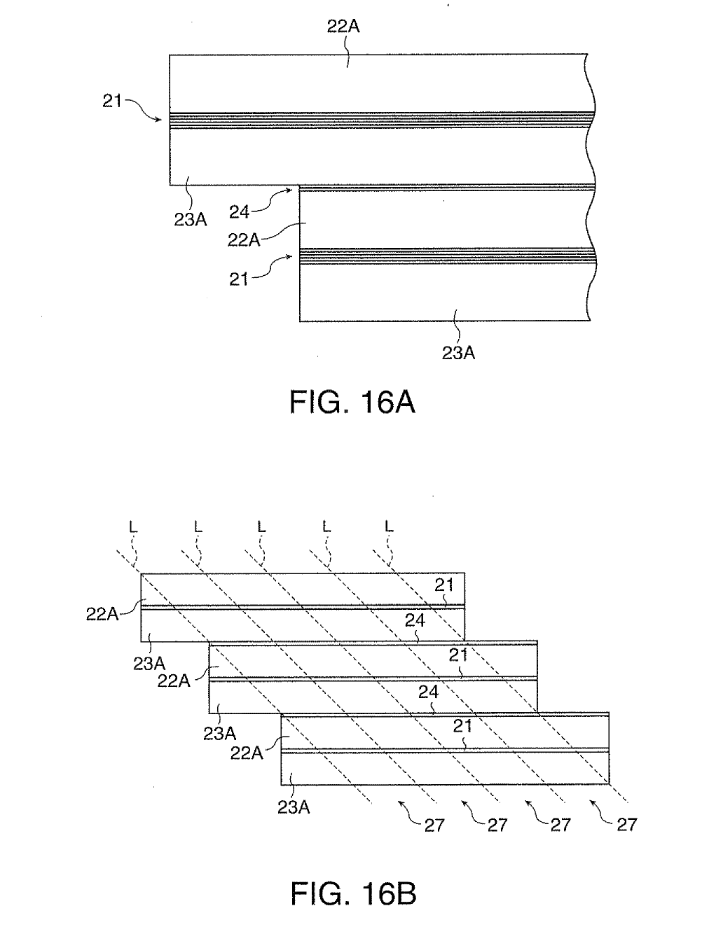

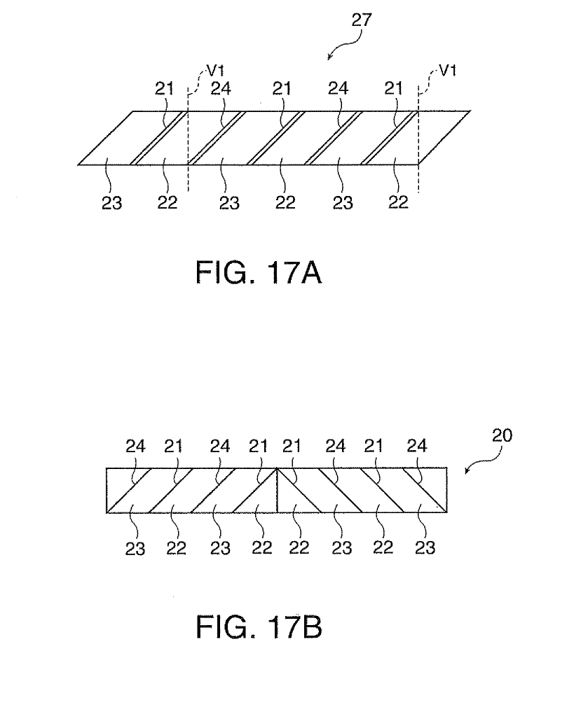

A manufacturing method of the optical element according to Second Embodiment is described below with reference to FIGS. 13A to 13C to FIGS. 17A and 17B. FIGS. 13A to 13C are schematic diagrams representing the procedure of molding the bonding film. FIGS. 14A and 14B are schematic diagrams explaining the activation step of the bonding film. FIGS. 15A and 15B are schematic diagrams explaining the bonding step. FIGS. 16A and 16B are schematic diagrams explaining the cutting step. FIGS. 17A and 17B are schematic diagram explaining the assembly step.

### Optical Function Film Forming Step

A strip-like optical block 23A for molding the first glass-base material 23, and a strip-like optical block 22A for forming the second glass-base material 22 are prepared.

The silicon oxide film 213 is formed on one surface of the strip-like optical block 23A, and, as illustrated in FIGS. 13A, 1313, and 13C, the bonding film 26A is formed on the silicon oxide film 213 provided on the strip-like optical block 23A (see FIGS. 12A and 12B).

Specifically, as illustrated in FIG. 13A, the uppermost layer of the silicon oxide film 21B provided on the strip-like optical block 23A is exposed to a mixed gas.

As a result, as illustrated in FIG. 13B, a polymerization product adheres and deposits on the uppermost layer surface of the silicon oxide film 21B. Then, as illustrated in FIG. 13C, a thin film portion 2631 is formed on the uppermost layer of the silicon oxide film 21B.

### Surface Activation Step

Thereafter, as illustrated in FIG. 14A, the surface of the thin film portion 26B1 is activated, for example, by plasma irradiation.

### Bonding Step

The thin film portion 2631 formed on the silicon oxide film 21B of the strip-like optical block 23A is bonded to the strip-like optical block 22A.

Though not illustrated, the strip-like optical block 22A is provided in advance with the ½ wave plate 21C laminated on the polarization separation film 21A via the bonding film 26B, and an activated thin film portion 26B2 formed on the ½ wave plate 21C.

As illustrated in FIG. 14B, the thin film portion 26B2 formed on the ½ wave plate 21C is disposed face to face with the thin film portion 26B1 formed on the silicon oxide film 21B. Then, as illustrated in FIGS. 15A and 15B, the thin film portion 26B1 of the strip-like optical block 23A, and the thin film portion 26B2 of the strip-like optical block 22A are bonded to each other to form the bonding film 26B.

Note that, in the present embodiment, the reflecting film 24 is formed on the strip-like optical blocks 23A and 22A, between which the polarization separation film 21A is provided. Specifically, the reflecting film 24 is formed on the strip-like optical block 22A by a method such as vapor deposition, and the bonding film (not illustrated) is formed in contact with the uppermost layer of the reflecting film 24. The bonding film is then bonded to the strip-like optical block 23A. The bonding is made with an offset at the end portion of the strip-like optical blocks 23A and 22A provided with the polarization separation-conversion layer 21 bonded in between (see FIG. 16A).

### Cutting Step

A laminate of a plurality of strip-like optical blocks 23A and 22A is then cut into a predetermined shape.

As illustrated in FIG. 16A, the strip-like optical blocks 23A and 22A are laminated with an offset at the end portion. The laminate of the strip-like optical blocks 23A and 22A is cut at predetermined intervals along the direction L creating a 45° angle with respect to the flat surface, as illustrated in FIG. 16B. FIG. 17A illustrates one of the blocks cut in this manner.

As illustrated in FIG. 17A, the block 27 has a cross section in the shape of a parallelogram. The block 27 is structured to include the polarization separation-conversion layer 21 and the reflecting film 24 disposed at predetermined intervals. The block 27 is then cut along the direction V1 perpendicular to the flat surface.

### Phase Difference Installing Step

As illustrated in FIG. 17B, the blocks 27 are disposed side by side, and bonded to each other to mold the polarization separation element 20.

The Second Embodiment of the configuration described above has the following advantages.

(14) The silicon oxide film 21B formed on the first glass-base material 23, and the ½ wave plate 21C are bonded to each other via the bonding film 263. The first glass-base material 23 and the ½ wave plate 21C are thus strongly bonded to each other.

(15) The polarization separation film 21A having the silicon oxide film on the outermost layer is bonded to the ½ wave plate 21C via the bonding film 26A. Thus, the polarization separation film 21A and the ½ wave plate 21C can be strongly bonded to each other.

Because the bond strength remains strong even under heat strain, detachment can be prevented between the first glass-base material 23, the polarization separation film 21A, and the ½ wave plate 21C.

### Third Embodiment

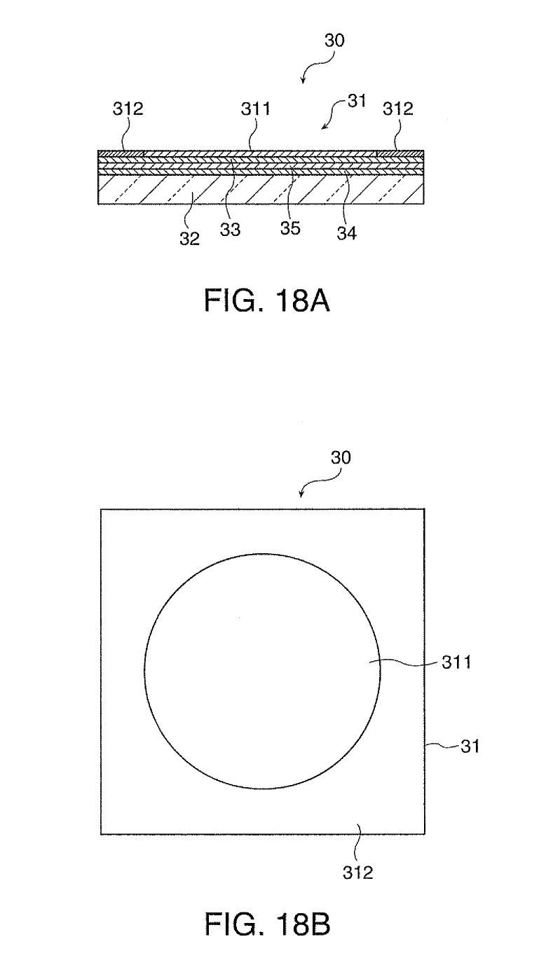

The following describes Third Embodiment of the present invention with reference to FIGS. 18A and 18B. FIG. 18A is a schematic plan view of an optical element provided with a bonding film-attached substrate according to Third Embodiment of the invention. FIG. 18B is a schematic structure view of the optical element.

Third Embodiment is an example of the optical element as an aperture filter 30. The aperture filter 30 is used by being incorporated in, for example, a pickup device.

As illustrated in FIGS. 18A and 18B, the aperture filter 30 of Third Embodiment includes a quartz crystal wave plate 31 (adherend), and a glass base material 32 provided as a substrate. Note that the glass base material 32 does not include silicon dioxide as the main component, or does not have a Si-group skeleton, and is, for example, a phosphate glass member.

The wave plate 31 includes a phase adjuster 311 and a wavelength selector 312. The phase adjuster 311 allows for passage of light beams of all wavelengths from among the light beams of different wavelengths. The wavelength selector 312 blocks the passage of a light beam of a predetermined wavelength.

A silicon oxide film 33 is formed on the surface of the wave plate 31 on the side of the glass base material 32. A silicon oxide film 34 is formed on the surface of the glass base material 32 on the side of the wave plate 31. The silicon oxide film 33 of the wave plate 31, and the silicon oxide film 34 of the glass base material 32 are bonded to each other via a bonding film 35 similar to that described in the First Embodiment.

The aperture filter 30 is manufactured as follows. As in First Embodiment, the silicon oxide films 33 and 34 are laminated on the wave plate 31 and the glass base material 32, respectively, using a method such as vapor deposition.

Then, an activated thin film portion is formed on the silicon oxide film 33 of the wave plate 31, and on the silicon oxide film 34 of the glass base material 32, and these thin film portions are bonded to each other to form the bonding film 35 and complete the aperture filter 30.

The Third Embodiment of the configuration described above has the following advantages.

(16) The silicon oxide films 33 and 34 are laminated on the wave plate 31 and the glass base material 32, respectively, and the bonding film 35 is formed between the silicon oxide films 33 and 34. This further improves the bond strength, and the bond strength can remain strong even under heat strain. Thus, the wave plate 31 and the glass base material 32 can be prevented from being detached from each other.

### Fourth Embodiment

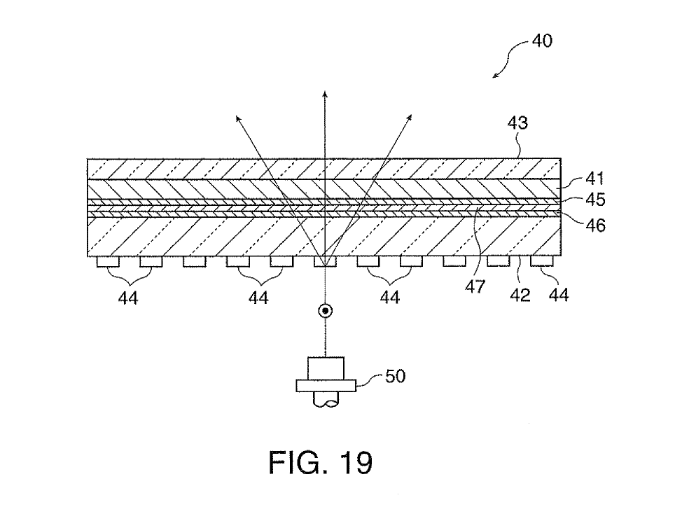

The following describes Fourth Embodiment of the present invention with reference to FIG. 19. FIG. 19 is a schematic plan view of an optical element provided with a bonding film-attached substrate according to Fourth Embodiment of the invention.

Fourth Embodiment is an example of the optical element as a diffraction grating-equipped wave plate 40 (hereinafter, simply “wave plate 40”). The wave plate 40 is used by being incorporated in, for example, a pickup device.

As illustrated in FIG. 19, the wave plate 40 of Fourth Embodiment is a laminate that includes a crystalline retardation plate 41 (adherend), a glass base material 42 provided as a substrate and bonded to a retardation plate 41, and a polarizing element 43 provided on the retardation plate 41 opposite from the glass base material 42. Note that the glass base material 42 does not include silicon dioxide as the main component, or does not have a Si-group skeleton, and is, for example, a phosphate glass member.

The polarizing element 43 is a wire grid with metallic fine periodic patterns.

A diffraction grating 44 is formed on the outer surface of the glass base material 42. The diffraction grating 44 is configured from a plurality of raised portions disposed at predetermined intervals on the surface of the glass base material 42.

The wave plate 40 splits the emitted light from a light source 50 into three beams through the diffraction grating 44.

A silicon oxide film 45, similar to that described in First Embodiment, is formed on the surface of the retardation plate 41 on the side of the glass base material 42. A silicon oxide film 46, similar to that described in First Embodiment, is formed on the surface of the glass base material 42 on the side of the retardation plate 41. The silicon oxide film 45 on the retardation plate 41, and the silicon oxide film 46 on the glass base material 42 are bonded to each other via a bonding film 47 similar to that described in First Embodiment.

The wave plate 40 is manufactured as follows. As in Third Embodiment, the silicon oxide films 45 and 46 are laminated on the retardation plate 41 and the glass base material 42, respectively, using a method such as vapor deposition.

Then, an activated thin film portion is formed on the silicon oxide film 45 of the retardation plate 41 and on the silicon oxide film 46 of the glass base material 42, and these thin film portions are bonded to each other to form a bonding film 47.

After bonding the retardation plate 41 and the glass base material 42, a polarizing element 43 is formed on the retardation plate 41, and a diffraction grating 44 is formed on the glass base material 42 to complete the wave plate 40. The polarizing element 43 may be, for example, a polarizing film made of resin, or an inorganic polarizer configured from inorganic material.

The Fourth Embodiment of the configuration described above has the following advantages.

(17) The silicon oxide films 45 and 46 are laminated on the retardation plate 41 and the glass base material 42, respectively, and the bonding film 47 is formed between the silicon oxide films 45 and 46. Thus, superior bond strength can be exhibited even under heat strain, and the retardation plate 41 and the glass base material 42 can be prevented from being detached from each other.

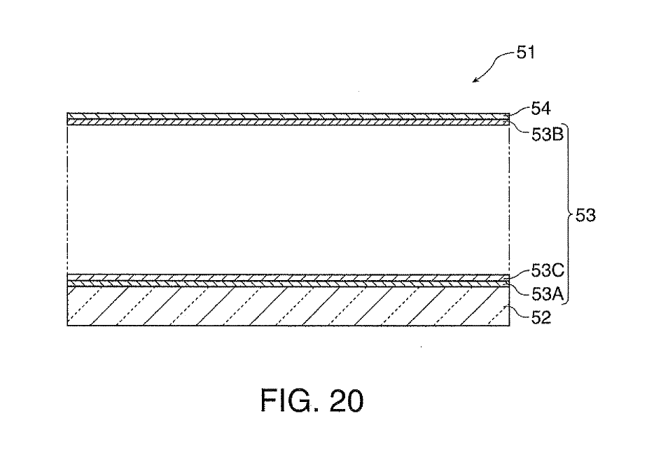

The invention is not limited to the foregoing embodiments, and various variations and modifications are confined within the scope of the invention, provided that the objects of the invention are attained. FIG. 20 is a schematic structure view representing a variation of the bonding film-attached substrate of the invention.

For example, the substrate, described as being a phosphate glass member in the foregoing First to Fourth Embodiments, is not limited to a phosphate glass member. The substrate may be a borosilicate glass as a mixture of SiO₂ and B₂O₃, or a YAG (yttrium aluminum garnet) substrate. The YAG substrate is a composite oxide of yttrium oxide (Y₂O₃) and aluminum oxide (Al₂O₃), and has a colorless transparent, cubical crystalline carbuncular structure. Further, the substrate may be a boron oxide glass substrate that contains boron oxide (B₂O₅) as the main component.

First Embodiment described the optical element that includes the IR absorbing glass member and the crystalline optical member (retardation plate 3 and crystalline birefringent plate 1). However, in the invention, the object bonded to the IR absorbing glass member is not limited to a crystalline object, and may be a silicon oxide glass optical member. As used herein, the silicon oxide glass is a glass or fused quartz that contains silicon oxide as the main component, and metal oxide or the like as an auxiliary component.

Further, though the foregoing First Embodiment described bonding the crystalline birefringent plate, the IR absorbing glass member, the retardation plate, and the crystalline birefringent plate, the invention is not limited to this. For example, in the invention, only the IR absorbing glass member and the retardation plate may be bonded, and the other members may be separately disposed. Further, only the crystalline birefringent plate, the IR absorbing glass member, and the retardation plate may be bonded, and the crystalline birefringent plate may be separately disposed.

Further, in the foregoing First to Fourth Embodiments, the thin film portion of the bonding film is formed on one surface of the adherend, whereas the silicon oxide film and the thin film portion of the bonding film are formed on the base material. However, the invention is not limited to this. In the invention, the adherend can remain free of deposition, provided that the silicon oxide film is formed on the base material, and that the bonding film is formed on the silicon oxide film. In this case, the activation step is performed for both the bonding film and the adherend.

Further, for example, as illustrated in FIG. 20, the bonding film-attached substrate 51 of an embodiment of the invention may include a substrate 52 similar to that described in First Embodiment, a bonding film 54 similar to that described in First Embodiment, and a multilayer film 53.

The multilayer film 53 includes silicon oxide films 53A and 53B similar to that described in First Embodiment, and one or more intermediate films 53C provided between these films. The silicon oxide film 53A is the outermost layer adjacent to the substrate 52. The silicon oxide film 53B is preferably the outermost layer adjacent to the bonding film 54.

The material of the intermediate film 53C may be, for example, zinc oxide (ZnO₂), tantalum oxide (Ta₂O₅), or titanium oxide (TiO₂).

The multilayer film 53 serves as a matching coating. For example, the multilayer film 53 can serve to reduce reflection at the interface between the silicon oxide film 53B and the bonding film 54.

The bonding film-attached substrate of the invention also can be used for elements other than optical elements such as the optical low-pass filter described above.

The invention is applicable to optical low-pass filters, and various optical apparatuses provided with the bonding film-attached substrate, including liquid crystal projectors and pickup devices.

The entire disclosure of Japanese Patent Application No. 2010-093741, filed Apr. 15, 2010 and Japanese Patent Application No. 2010-259548, filed Nov. 19, 2010 are expressly incorporated by reference herein.

17. A bonding film-attached substrate, comprising:
a substrate whose main component is not silicon dioxide, or that does not have a Si-group skeleton;
a silicon oxide film formed on a surface of the substrate and adjacent to the substrate using a vapor-phase deposition method, and that has a thickness of from 100 nm to 2,000 nm, inclusive; and
a bonding film provided by plasma polymerization, wherein the bonding film includes (i) a Si skeleton that contains a siloxane (Si—O) bond, and has a crystallinity of 45% or less, and (ii) an elimination group that binds to the Si skeleton, the elimination group being an organic group.

18. The bonding film-attached substrate according to claim 17, wherein the bonding film bonds the substrate and an adherend by an active hand, wherein the active hand is a non-bonding hand of a silicon atom of a Si-skeleton where elimination group removes from the silicon atom of the Si-skeleton.

19. The bonding film-attached substrate according to claim 17, wherein a total content of Si atoms and O atoms in all atoms forming the bonding film excluding H atoms is from 10 atom % to 90 atom %, inclusive.

20. The bonding film-attached substrate according to claim 17, wherein the ratio of Si atoms and O atoms present in the bonding film is 3:7 to 7:3.

21. The bonding film-attached substrate according to claim 17, wherein the elimination group is an alkyl group.

22. The bonding film-attached substrate according to claim 17, wherein the bonding film has an unbound atom or a hydroxyl group as an active bond after the elimination of the elimination group from the Si skeleton at least in the vicinity of the bonding film surface.

23. The bonding film-attached substrate according to claim 17, wherein the bonding film includes polyorganosiloxane as a main material, and wherein a polymerization product of octamethyltrisiloxane is the main component of the polyorganosiloxane.

24. The bonding film-attached substrate according to claim 17, wherein the substrate is a phosphate glass substrate.

25. The bonding film-attached substrate according to claim 17, wherein a peak intensity ratio attributed to a methyl group is 0.05 or more and 0.15 or less with respect to the peak intensity 1 attributed to the siloxane bond in an infrared absorption spectrum.

26. The bonding film-attached substrate according to claim 17, wherein a peak intensity ratio attributed to a Si—CH₃ bond is 0.29 or more and 0.76 or less with respect to the peak intensity 1 attributed to the siloxane bond in an infrared absorption spectrum.

27. The bonding film-attached substrate according to claim 17, wherein the bonding film is activated by a plasma.

28. The bonding film-attached substrate according to claim 17, wherein the bonding film-attached substrate is used for an optical low-pass filter.

29. The bonding film-attached substrate according to claim 17, wherein the bonding film-attached substrate is used for a polarization separation element.

30. The bonding film-attached substrate according to claim 28,
wherein a polarization separation film is provided on the substrate in a portion facing the bonding film, wherein the polarization separation film is configured as a plurality of layers that includes the silicon oxide film and a magnesium fluoride thin film, the silicon oxide film being adjacent to the bonding film.

31. The bonding film-attached substrate according to claim 17, wherein the bonding film-attached substrate is used for an aperture filter.

32. The bonding film-attached substrate according to claim 17, wherein the bonding film-attached substrate is used for a wave plate equipped with a diffraction grating.

33. A method for manufacturing the bonding film-attached substrate of claim 17,
the method comprising:
forming the silicon oxide film on the substrate by sputtering or vapor deposition in a temperature range of from 150° C. to 350° C., inclusive; and
forming the bonding film by using plasma polymerization in a temperature range of from 40° C. to 150° C., inclusive.
